(19) United States
(12) Patent Application Publication
(10) Pub. No.: US 2024/0280889 A1
(43) Pub. Date: Aug. 22, 2024

(54) EXTREME ULTRAVIOLET MASK AND METHOD OF MANUFACTURING THE SAME

(71) Applicant: SAMSUNG ELECTRONICS CO., LTD., SUWON-SI (KR)

(72) Inventors: Sunpyo Lee, Suwon si (KR); Minchang Kim, Suwon si (KR); Yoontaek Han, Suwon si (KR)

(21) Appl. No.: 18/413,399

(22) Filed: Jan. 16, 2024

(30) Foreign Application Priority Data
Feb. 17, 2023 (KR) 10-2023-0021593

(51) Int. Cl. G03F 1/24

(52) U.S. Cl. CPC G03F 1/24

(57) ABSTRACT

Provided are an extreme ultraviolet (EUV) mask having enhanced reliability and durability and a method of manufacturing the same. The EUV mask includes a substrate having a rectangular shape, a reflective multilayer positioned on the substrate and having dozens of alternating layers of two different materials, in which an edge slope area or a vertical end is formed at an outer edge portion of the reflective multilayer, and an absorption layer positioned on at least a portion of the reflective multilayer. The EUV mask may have a defect avoidance pattern which opens the edge slope area or the vertical end.

### CROSS-REFERENCE TO RELATED APPLICATION

This application claims priority under 35 U.S.C. § 119 to Korean Patent Application No. 10-2023-0021593, filed on Feb. 17, 2023, in the Korean Intellectual Property Office, the disclosure of which is incorporated by reference herein in its entirety.

### TECHNICAL FIELD

The present inventive concept relates to a mask and a method of manufacturing the same, and more particularly, to an extreme ultraviolet (EUV) mask used in an EUV exposure process and a method of manufacturing the same.

### DISCUSSION OF RELATED ART

To meet the excellent performance and low price required by consumers, the sizes of patterns formed on semiconductor substrates are getting smaller and smaller. This continuing demand in view of the ever increasing desire in the semiconductor industry for higher circuit density in microelectronic devices has prompted lithographic engineers to develop better lithographic processes. Accordingly, the wavelength of a light source used in a lithography process is getting shorter and shorter to meet these technical requirements. For example, in the lithography process, g-line (436 nm) and i-line (365 nm) were used in the past, but now deep ultraviolet (DUV) light and extreme ultraviolet (EUV) light are being used. Since most of the EUV light is absorbed in refractive optical materials, EUV lithography may generally be performed using a reflective optical system rather than a refractive optical system. An EUV mask, which is a reflective mask, may include a substrate, a multilayer reflector, and an absorption layer selectively etched to form absorption patterns, and may also contain a capping layer. Since EUV masks are more complex than traditional photomasks, it is harder to make defect-free EUV masks.

### SUMMARY

The present inventive concept provides an extreme ultraviolet (EUV) mask with enhanced reliability and durability and a manufacturing method thereof.

According to an embodiment of the present inventive concept, there is provided an EUV mask including a substrate having a rectangular shape, a reflective multilayer positioned on the substrate and having dozens of alternating layers of two different materials, in which an edge slope area or a vertical end is formed at an outer edge portion of the reflective multilayer, and an absorption layer positioned on at least a portion of the reflective multilayer, in which the EUV mask has a defect avoidance pattern which opens the edge slope area or the vertical end.

According to an embodiment of the present inventive concept, there is provided an EUV mask including a substrate having a rectangular shape, a reflective multilayer positioned on the substrate and having dozens of alternating layers of two different materials, in which an edge slope area or a vertical end is formed at an outer edge portion of the reflective multilayer, a capping layer having a first capping layer on the reflective multilayer and a second capping layer on the substrate outside the reflective multilayer, and an absorption layer including a first absorption layer disposed on at least a portion of the first capping layer and a second absorption layer disposed on at least a portion of the second capping layer, in which the EUV mask has a defect avoidance pattern which opens a portion of the capping layer covering the edge slope area or a portion of the substrate between the vertical end and the second capping layer.

According to an embodiment of the present inventive concept, there is provided an EUV mask including a substrate having a rectangular shape, a reflective multilayer positioned on the substrate and having dozens of alternating layers of two different materials, in which an edge slope area is formed at an outer edge portion of the reflective multilayer, a capping layer on the reflective multilayer, and an absorption layer disposed on at least a portion of the capping layer, in which the EUV mask has a defect avoidance pattern which opens the edge slope area or a portion of the capping layer covering the edge slope area.

According to an embodiment of the present inventive concept, there is provided a method of manufacturing an EUV mask, the method including forming a reflective multilayer by alternately stacking dozens of layers of two different materials on a substrate, forming, on the reflective multilayer, an absorption layer divided into a central transfer area and a non-transfer area outside the transfer area, forming a defect avoidance pattern which opens an edge slope area of the reflective multilayer in the non-transfer area or opens a portion of a top surface of the substrate corresponding to the edge slope area, and forming an absorption pattern in the absorption layer.

According to an embodiment of the present inventive concept, there is provided a method of manufacturing an EUV mask, the method including forming a reflective multilayer by alternately stacking dozens of layers of two different materials on a substrate, forming, on the reflective multilayer, an absorption layer divided into a central transfer area and a non-transfer area outside the transfer area, and forming an absorption pattern on the absorption layer, in which in the forming of the reflective multilayer, the reflective multilayer is formed to cover a top surface of the substrate and extending from the top surface of the substrate to cover a side surface of the substrate.

### BRIEF DESCRIPTION OF THE DRAWINGS

Embodiments of the present inventive concept will be more clearly understood from the following detailed description taken in conjunction with the accompanying drawings, in which:

FIG. 1 is a plan view of an extreme ultraviolet (EUV) mask according to an embodiment of the present inventive concept;

FIGS. 2A, 2B, 3A, 3B, 4A, 4B, 5A and 5B are plan views and cross-sectional views showing an enlarged portion A of the EUV mask of FIG. 1;

FIGS. 6A to 6E are a plan view, a cross-sectional view, and pictures showing the defects of an EUV mask of a comparative example;

FIGS. 7A to 7C are a plan view of an EUV mask of a comparative example, and a plan view and a cross-sectional view of an EUV mask according to an embodiment of the present inventive concept;

FIG. 8 is a flowchart schematically illustrating a method of manufacturing the EUV mask of FIG. 1 according to an embodiment of the present inventive concept;

FIGS. 9A, 9B, 10A, 10B, 11A, 11B, 12A and 12B are plan views and cross-sectional views of an EUV mask corresponding to operations of the method of manufacturing the EUV mask of FIG. 8;

FIG. 13 is a flowchart schematically illustrating a method of manufacturing the EUV mask of FIG. 7B according to an embodiment of the present inventive concept;

FIGS. 14A, 14B, 15A and 15B are plan views and cross-sectional views of an EUV mask corresponding to operations of the method of manufacturing the EUV mask of FIG. 13;

FIG. 16 is a flowchart schematically illustrating a method of manufacturing an EUV mask according to an embodiment of the present inventive concept; and

FIGS. 17A and 17B are a plan view and a cross-sectional view of an EUV mask corresponding to an operation of forming a reflective multilayer in the method of manufacturing the EUV mask of FIG. 16.

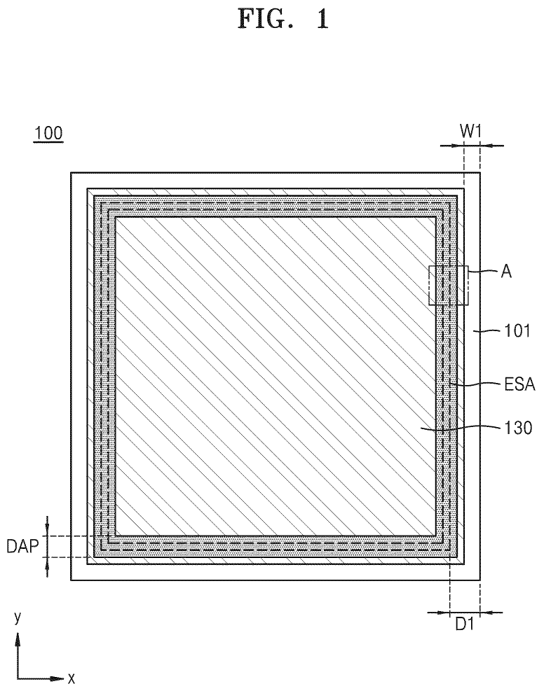

Since the drawings in FIGS. 1-17B are intended for illustrative purposes, the elements in the drawings are not necessarily drawn to scale. For example, some of the elements may be enlarged or exaggerated for clarity purpose.

### DETAILED DESCRIPTION OF THE EMBODIMENTS

Hereinafter, embodiments of the present inventive concept will be described in detail with reference to the accompanying drawings. The same reference numerals are used for the same components in the drawings, and duplicate descriptions thereof are omitted.

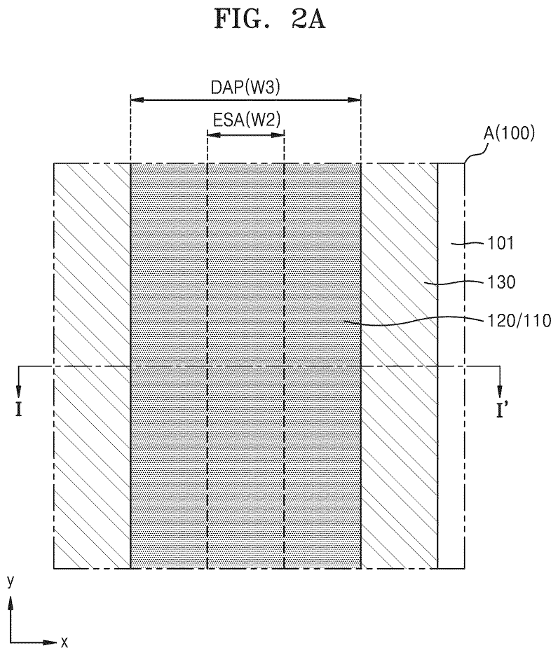

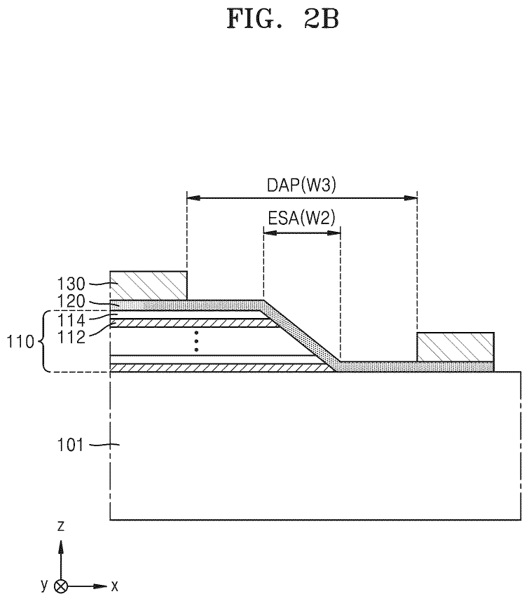

FIG. 1 is a plan view of an extreme ultraviolet (EUV) mask according to an embodiment of the present inventive concept, and FIGS. 2A to 5B are plan views and cross-sectional views showing an enlarged portion A of the EUV mask of FIG. 1. FIGS. 2A, 3A, 4A, and 5A are plan views each showing an enlarged portion A of FIG. 1, and FIGS. 2B, 3B, 4B, and 5B are cross-sectional views taken along lines I-I′ of FIGS. 2A, 3A, 4A, and 5A, respectively.

Referring to FIGS. 1, 2A, and 2B, an EUV mask 100 according to an embodiment of the present inventive concept may include a substrate 101, a reflective multilayer 110, a capping layer 120, and an absorption layer 130. For example, the reflective multilayer 110, the capping layer 120, and the absorption layer 130 may be sequentially stacked on the substrate 101. As shown in FIG. 1, the substrate 101, the reflective multilayer 110, the capping layer 120, and the absorption layer 130 may each have a rectangular shape in plan view.

The substrate 101 may have a largest size. Accordingly, a top surface of an outer portion of the substrate 101 may be exposed in a rectangular frame shape. The exposed outer portion of the substrate 101 may also be referred to as an open area of an edge portion of the substrate 101. A first width W1 of the exposed portion of the substrate 101 may be, for example, about 1.0 mm or more. The first width W1 may be defined in a direction perpendicular to a direction in which the exposed portion extends. For example, the shortest distance from an edge of the substrate to the portion of the substrate not being exposed may be about 1.0 mm or more. For example, in FIG. 1, the first width W1 of upper and lower sides of the exposed portion of the substrate 101 extending in an X direction may be defined in a Y direction, and the first width W1 of left and right sides of the exposed portion of the substrate 101 extending in the Y direction may be defined in the X direction. The first width W1 is not limited to the above numerical range.

“About” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

The substrate 101 may include a low thermal expansion material (LTEM). The low thermal expansion quality of the substrate 101 is a feature adopted to prevent the mask from warping or otherwise distorting the image. In other words, the substrate 101 may include a material having a low coefficient of thermal expansion (CTE). For example, the substrate 101 may include glass, silicon (Si), quartz, or the like. In an embodiment of the present inventive concept, the substrate 101 may include an ultra-low expansion glass. In an embodiment of the present inventive concept, the substrate 101 may include a titanium oxide (TiO₂) doped silicon oxide (SiO₂) glass. However, the material of the substrate 101 is not limited to the above materials.

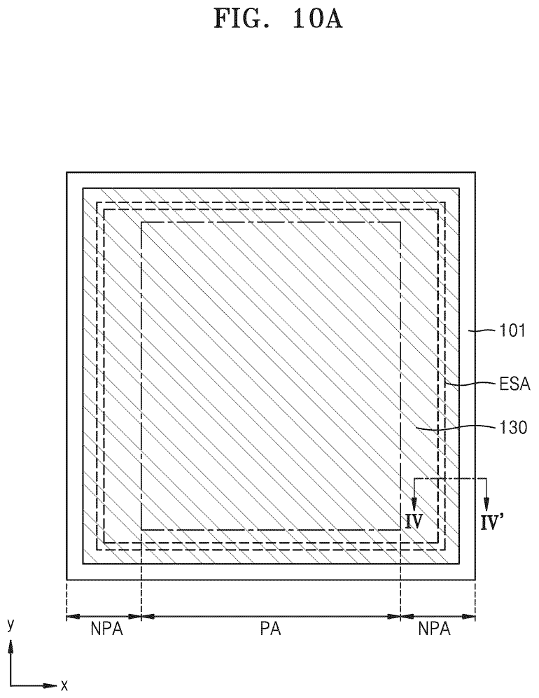

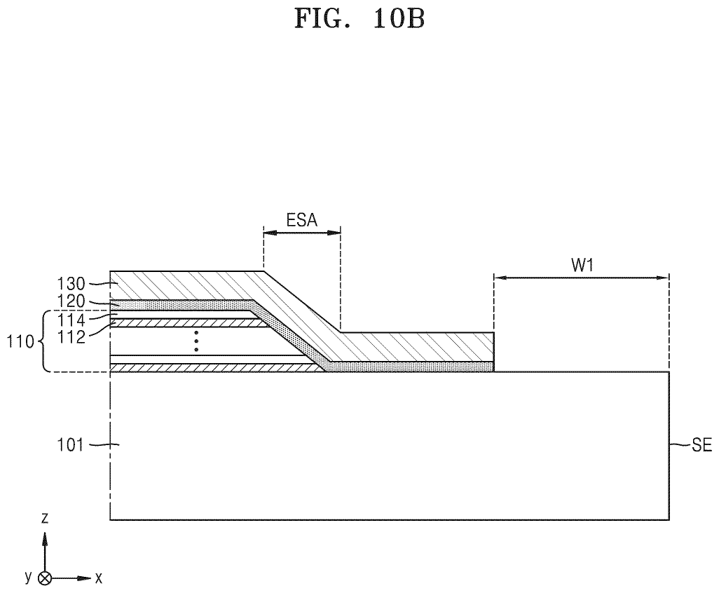

A transfer area (see PA of FIG. 10A) and a non-transfer area (see NPA of FIG. 10A) may be defined on the substrate 101. The transfer area PA may be positioned in a central portion of the substrate, and the non-transfer area NPA may be positioned in the outer portion of the substrate 101 to surround the transfer area PA. The transfer area PA may refer to an area where patterns to be transferred onto a wafer through an EUV exposure process are arranged. The non-transfer area NPA may not have patterns to be transferred onto the wafer, but may have various marks such as alignment marks. The patterns to be transferred onto the wafer may be formed on the absorption layer 130. The absorption layer 130 is a layer having a function of absorbing EUV light. The absorption layer 130 may also be divided into a transfer area PA and a non-transfer area NPA corresponding to the transfer area PA and the non-transfer area NPA of the substrate 101, respectively. Thus, the patterns to be transferred onto the wafer may be arranged in the transfer area PA of the absorption layer 130. Accordingly, EUV light may be absorbed by the absorption layer 130 or may be reflected based on the patterns to be transferred.

The reflective multilayer 110 may be disposed on the substrate 101. The reflective multilayer 110 may reflect light, e.g., EUV rays, incident on the reflective multilayer 110. The reflective multilayer 110 may include a Bragg reflector where a periodic stack of two different materials causes EUV rays to constructively interfere and reflect. In the EUV mask 100 according to an embodiment of the present inventive concept, the reflective multilayer 110 may have a multilayer structure in which dozens of alternating layers of two different materials are stacked. Here and throughout the specification and claims, the word “dozens” is not limited to a group of twelve, but may mean “a few or a lot”. For example, the reflective multilayer 110 may include first material layers 112 and second material layers 114 that are alternately stacked. Accordingly, the second material layer 114 may be positioned between a pair of adjacent first material layers 112, and conversely, the first material layer 112 may be positioned between a pair of adjacent second material layers 114. In the EUV mask 100 according to an embodiment of the present inventive concept, the number of each of the first material layers 112 and the second material layers 114 that are alternately stacked may be about 40 to about 60. However, the number of each of the first material layers 112 and the second material layers 114 is not limited to the above numerical range.

The first material layer 112 may be a low refractive index layer, and the second material layer 114 may be a high refractive index layer. The reflective multilayer 110 having the high refractive index layers and low refractive index layers alternately stacked may be capable of reflecting light of a specific wavelength. Accordingly, the second material layers 114 may have a refractive index higher than that of the first material layers 112. For example, the first material layers 112 may include molybdenum (Mo), and the second material layers 114 may include silicon (Si). The Mo/Si multilayer reflective film with layers of Mo and Si alternately stacked for about 40 to 60 cycles may have high reflectance of EUV light having about 13 to 14 nm wavelength. Other combinations of two different suitable materials may also be used, for example, ruthenium (Ru) and silicon (Si), molybdenum (Mo) and beryllium (Be), or silicon (Si) and niobium (Nb). However, the materials of the first material layers 112 and the second material layers 114 are not limited to the above materials. For example, in the EUV mask 100 according to an embodiment of the present inventive concept, the first material layer 112, which is a low refractive index layer, may be disposed on a lowermost portion of the reflective multilayer 110, and the second material layer 114, which is a high refractive index layer, may be disposed on an uppermost portion of the reflective multilayer 110.

The reflective multilayer 110 may include an edge slope area ESA at four edges due to limitations in a manufacturing process. In the edge slope area ESA, a height of the reflective multilayer 110 may gradually decrease toward the outer portion. In other words, the low end (i.e., lowest point) of the edge slope area ESA is located toward the edge of the substrate 101, while the high end (i.e., highest point) of edge slop area ESA is located toward the center of the substrate 101. An area of the reflective multilayer 110 may be defined by an outermost portion of the edge slope area ESA. Accordingly, as shown in FIGS. 1 and 2B, the area of the reflective multilayer 110 may be smaller than the areas of the substrate 101, the capping layer 120, and the absorption layer 130.

As shown in FIG. 1, the edge slope area ESA may have a rectangular frame or a rectangular ring shape, in plan view, located at and surrounding along the outer portion of the EUV mask 100. In addition, the edge slope area ESA may be formed at a certain distance from an edge of the substrate 101. For example, in the EUV mask 100 according to an embodiment of the present inventive concept, a distance from the outermost portion of the edge slope area ESA to the edge of the substrate 101, i.e., first distance D1, may be about 2 mm or more. However, the first distance D1 is not limited to the above numerical range. In addition, in plan view, the edge slope area ESA may have a second width W2 in a direction perpendicular to a direction extending in a rectangular ring shape, e.g., X direction in FIG. 2A. For example, in FIG. 2A, the width direction (X direction) of the edge slope area ESA is perpendicular to a longitudinal direction (Y direction) in which the edge slope area ESA extends. The second width W2 may be, for example, about 0.5 mm. However, the second width W2 is not limited to the above value.

The capping layer 120 may be disposed on the reflective multilayer 110. For example, the capping layer 120 may cover a top surface of the reflective multilayer 110 and an inclined surface of the edge slope area ESA. In addition, according to an embodiment of the present inventive concept, the capping layer 120 may cover only the top surface of the reflective multilayer 110. Furthermore, the capping layer 120 extending from the inclined surface of the edge slope area ESA may cover the top surface of the outer portion of the substrate 101. The capping layer 120 may prevent damage to the reflective multilayer 110 and surface oxidation of the reflective multilayer 110. For example, in the manufacturing process, such as, for example, dry etching and wet cleaning, the capping layer 120 may also prevent the reflective multilayer 110 from being damaged. In the EUV mask 100 according to an embodiment of the present inventive concept, the capping layer 120 may cover a top surface of the second material layer 114 of, e.g., Si, to prevent the second material layer 114 from being oxidized. For example, the capping layer 120 may include ruthenium (Ru). When the capping layer 120 includes Ru, the reflective multilayer 110 may have good reflectance property. Alternatively, the capping layer 120 may include an alloy of Ru. However, the material of the capping layer 120 is not limited to Ru or an alloy of Ru. The capping layer 120 may be optional. Accordingly, in an embodiment of the present inventive concept, the capping layer 120 may be omitted.

The absorption layer 130 may be disposed on the capping layer 120. When the capping layer 120 is omitted, the absorption layer 130 may be directly disposed on the reflective multilayer 110, e.g., second material layer 114. The absorption layer 130 may be divided into a central transfer area (see PA in FIG. 10A) and a peripheral non-transfer area (see NPA in FIG. 10A). As described above with respect to the substrate 101, absorption patterns to be transferred onto a wafer through an EUV exposure process may be arranged in the transfer area PA of the absorption layer 130. For example, EUV light may be absorbed by the absorption layer 130 or may be reflected by the reflective multilayer 110 based on the absorption patterns arranged in the transfer area PA of the absorption layer 130.

The EUV mask 100 may be an EUV blank mask or an EUV finished mask, according to an embodiment of the present inventive concept. The EUV blank mask, which is a mask before absorption patterns are formed, i.e., before exposure, may not include a photo-resist (PR) layer on the absorption layer 130. In contrast, the EUV finished mask, as a relative concept to the EUV blank mask, may include absorption patterns in the absorption layer 130. In other words, the EUV finished mask may be manufactured by forming the absorption patterns in the absorption layer 130 of the EUV blank mask.

The absorption layer 130 may include a material that absorbs light, e.g., EUV rays, incident on the absorption layer 130. Accordingly, the EUV rays incident on the absorption layer 130 may not reach the capping layer 120 or the reflective multilayer 110. The absorption layer 130 may include, e.g., tantalum nitride (TaN), tantalum hafnium (TaHf), tantalum hafnium nitride (TaHfN), tantalum boron silicide (TaBSi), tantalum boron silicon nitride (TaBSiN), tantalum boride (TaB), tantalum boron nitride (TaBN), tantalum silicide (TaSi), tantalum silicon nitride (TaSiN), tantalum germanide (TaGe), tantalum germanium nitride (TaGeN), tantalum zirconium (TaZr), tantalum zirconium nitride (TaZrN), or combinations thereof. However, the material of the absorption layer 130 is not limited to the above materials.

For reference, the EUV rays incident to the capping layer 120 exposed through an open area of the absorption layer 130 may pass through the capping layer 120 and reach the reflective multilayer 110. In addition, the EUV rays may be reflected by the reflective multilayer 110 and irradiated onto a wafer to be exposed. Accordingly, the pattern transferred onto the wafer may correspond to the shape of the open area of the absorption layer 130.

A defect avoidance pattern DAP may be formed in the non-transfer area NPA of the absorption layer 130. As shown in FIG. 1, in plan view, the defect avoidance pattern DAP may have a rectangular frame or a rectangular ring shape surrounding along four sides of the EUV mask 100. For example, the defect avoidance pattern DAP may have a rectangular ring shape located at and surrounding along the outer portion of the EUV mask 100. For Example, the defect avoidance pattern DAP may have a rectangular ring shape located at the outer portion of the EUV mask 100 to surround the central portion of the EUV mask 100. In addition, as shown in FIG. 2B, the defect avoidance pattern DAP may have a shape penetrating the absorption layer 130 in a vertical direction. For example, the absorption layer 130 may be removed at the defect avoidance pattern DAP to expose the capping layer 120. The vertical direction may refer to a Z direction perpendicular to the top surface of the substrate 101. The defect avoidance pattern DAP having a rectangular ring-shape may be integrally connected. Accordingly, the defect avoidance pattern DAP may have a single pattern structure in the form of a rectangular ring.

The defect avoidance pattern DAP may open the edge slope area ESA of the reflective multilayer 110, or a corresponding portion of the capping layer 120 (i.e., a portion of the capping layer 120 corresponding to the edge slope area ESA) when the edge slope area ESA is covered by the capping layer 120 (hereinafter, “edge slope area ESA” and “corresponding portion of the capping layer 120” are collectively referred to as “edge slope area ESA”). Here, the language “open the edge slope area ESA of the reflective multilayer 110” may mean to remove any layer(s) above the edge slope area ESA of the reflective multilayer 110 to expose the edge slope area ESA of the reflective multilayer 110. If the edge slope area ESA is covered by the capping layer 120, the language “open the edge slope area ESA of the reflective multilayer 110” may also mean to remove any layer(s) above the corresponding portion of the capping layer 120 to expose the corresponding portion of the capping layer 120. Thus, the reflective multilayer 110 may include the edge slope area ESA, and after the formation of the defect avoidance pattern DAP to open the edge slope area ESA of the reflective multilayer 110, the absorption layer 130 may be divided to include a first portion (which may also be referred to as a first absorption layer) covering a portion of the reflective multilayer 110 and a second portion (which may also be referred to as a second absorption layer) covering a portion of the substrate 101 outside the reflective multilayer 110. In other words, the defect avoidance pattern DAP may open the edge slope area ESA between the first portion and the second portion of the absorption layer 130. Since the capping layer 120 may cover the top surface of the reflective multilayer 110, the inclined surface of the edge slope area ESA, and the top surface of a portion of the substrate 101 outside the edge slope area ESA toward an edge SE of the substrate 101, the defect avoidance pattern DAP may open the capping layer 120 corresponding to the edge slope area ESA. Here, the language “open the capping layer 120 corresponding to the edge slope area ESA” may mean to remove any layer(s) above the capping layer 120 corresponding to the edge slope area ESA to expose the capping layer 120 corresponding to the edge slope area ESA. In the EUV mask 100 according to an embodiment of the present inventive concept, by opening the edge slope area ESA through the defect avoidance pattern DAP, blister defects may be prevented or minimized in an exposure process using the EUV mask 100. The blister defect may refer to a defect in which a gap between the reflective multilayer 110 and the capping layer 120 is lifted by blisters. When the capping layer 120 is omitted, the blister defect may refer to a defect in which a gap between the reflective multilayer 110 and the absorption layer 130 is lifted by blisters. Blister defects may have higher absorption hence causing a reduction of EUV reflectance, and may scatter more light due to higher roughness and thus may lead to a significant reduction of EUV reflectance. Due to the reduction of the EUV reflectance by the blister defects, the patterns transferred to the wafer may be distorted, and thus causing a reliability concern of the EUV mask.

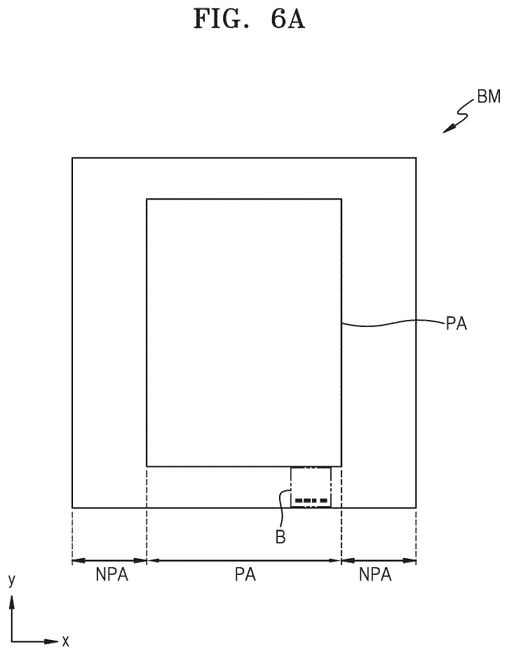

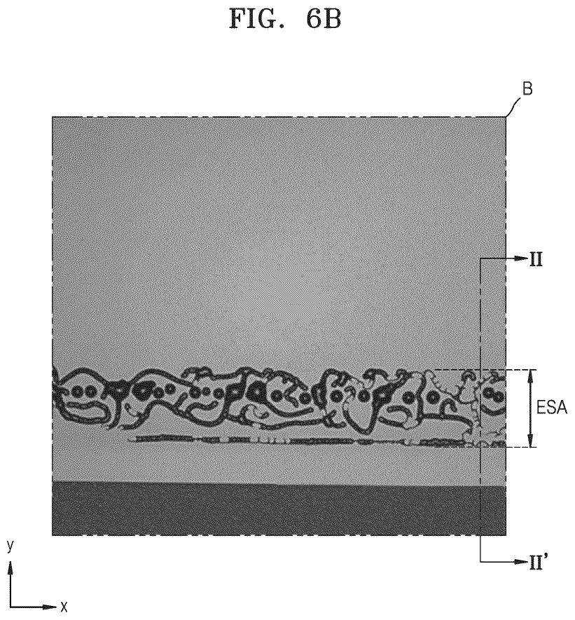

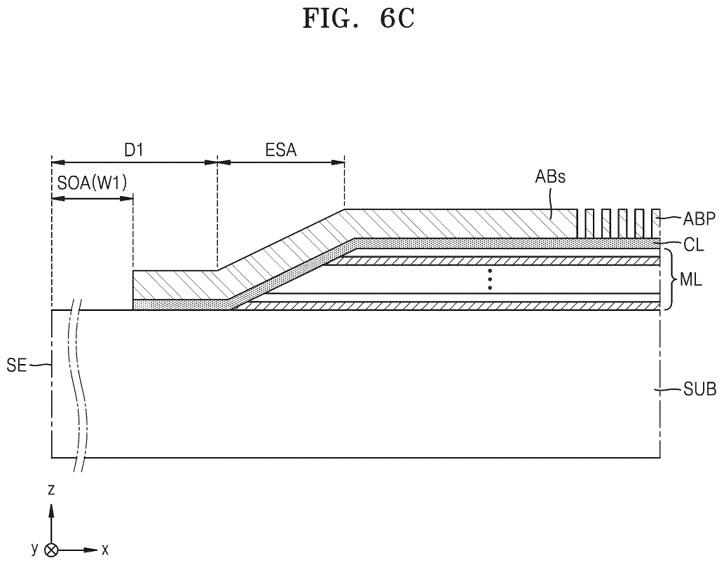

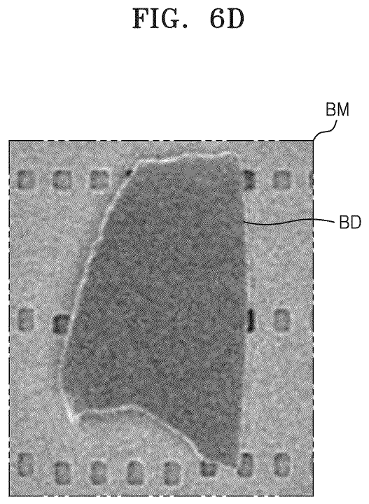

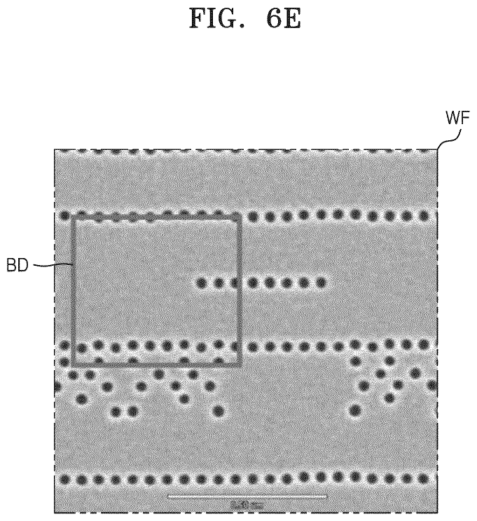

To describe the blister defect in more detail, impurities, e.g., carbon-containing impurities, may be formed on a surface of the EUV mask during the EUV exposure process. Hydrogen (H₂) gas may be supplied on the EUV mask to remove these impurities. However, hydrogen (H₂) gas may be dissociated by EUV rays, and the dissociated hydrogen atoms (H*) may enter the inside of the EUV mask and enter between the reflective multilayer 110 and the capping layer 120. In addition, hydrogen (H₂) gas may be accumulated between the reflective multilayer 110 and the capping layer 120 by recombination of hydrogen atoms (H*) entering between the reflective multilayer 110 and the capping layer 120, and blister defects in which a gap between the reflective multilayer 110 and the capping layer 120 is lifted due to the accumulated hydrogen (H₂) gas may occur. For example, when the hydrogen atom (H*) concentration is high enough, bubbles of gaseous hydrogen (H₂) compounds may be formed to lift the capping layer 120 above these bubbles. In the EUV mask 100 according to an embodiment of the present inventive concept, since the defect avoidance pattern DAP that opens the edge slope area ESA is formed, the hydrogen (H₂) gas may be discharged through the defect avoidance pattern DAP to effectively prevent the blister defects. Accordingly, reliability and durability of the EUV mask 100 may be greatly enhanced. The blister defects are described later in more detail with reference to FIGS. 6A to 6E.

In the EUV mask 100 according to an embodiment of the present inventive concept, the defect avoidance pattern DAP may have an area larger than that of the edge slope area ESA, in which the area may be defined on a plane parallel to the top surface of the substrate 101. For reference, since the edge slope area ESA includes an inclined surface, the inclined surface may be considered in defining the area. However, since the defect avoidance pattern DAP includes both an inclined surface and a flat surface, the area is defined on a plane parallel to the top surface of the substrate 101 for the convenience of comparison. For example, an area of the inclined surface and an area of a flat surface vertically overlapped by the inclined surface may have the same size.

The areas of the edge slope area ESA and the defect avoidance pattern DAP may be compared through a comparison of widths thereof because the edge slope area ESA and the defect avoidance pattern DAP both have a rectangular ring shape. For example, in FIG. 2A or FIG. 2B, the edge slope area ESA may have a second width W2 in the X direction, and the defect avoidance pattern DAP may have a third width W3 in the X direction. The third width W3 may be greater than the second width W2. In addition, as shown in FIG. 2A or FIG. 2B, the edge slope area ESA may be positioned inside the defect avoidance pattern DAP. For example, the defect avoidance pattern DAP may expose the portion of the capping layer 120 corresponding to the edge slope area ESA. As shown in FIG. 2A or FIG. 2B, the edge slope area ESA may be positioned in the central portion of the defect avoidance pattern DAP in the X direction. However, according to an embodiment of the present inventive concept, the edge slope area ESA may be positioned to be biased to one side in the X direction, or may be positioned such that at least a portion thereof is opened through the defect avoidance pattern DAP.

When the second width W2 of the edge slope area ESA in the X direction is about 500 μm, the third width W3 of the defect avoidance pattern DAP in the X direction may be twice or more than the second width W2. For example, the third width W3 may be equal to or greater than 1000 μm, and may be about 1500 μm in FIG. 2A, which is three times the second width W2. However, the third width W3 is not limited to the above numerical range. Theoretically, the third width W3 of the defect avoidance pattern DAP should be 500 μm or more. However, the third width W3 may have a width twice or more than the second width W2 to completely open the edge slope area ESA for reproducibility of equipment/process.

In the EUV mask 100 according to an embodiment of the present inventive concept, the defect avoidance pattern DAP may be arranged to prevent blister defects from occurring in the edge slope area ESA during the EUV exposure process. for example, in the EUV mask 100 according to an embodiment of the present inventive concept, the defect avoidance pattern DAP may be formed on the absorption layer 130 to open the edge slope area ESA, and, accordingly, hydrogen (H₂) gas accumulated between the reflective multilayer 110 and the capping layer 120 corresponding to the edge slope area ESA may be discharged through the defect avoidance pattern DAP to effectively prevent blister defects. Accordingly, reliability and durability of the EUV mask 100 may be greatly enhanced.

To prevent general blister defects in an EUV mask, patterns or holes may be formed in the transfer area PA of the absorption layer. These patterns or holes are called anti-blister patterns (ABPs) or anti-blister pattern holes (ABPHs). The ABPH refers to a hole formed in the absorption layer and the ABP refers to a pattern formed through the ABPH, but hereinafter they are referred to as ABP. Since the ABP should not be transferred to the wafer, the ABP may be formed in a size smaller than a minimum line width defined by the resolution of the EUV process. The size of the ABP and the minimum line width defined by the resolution of the EUV process described here are in the EUV mask level. When the EUV exposure tool has 4× magnification, the line width of a feature on the EUV mask will be four times of the line width of the feature printed on the wafer. When the EUV exposure tool has 8× magnification, the line width of a feature on the EUV mask will be eight times of the line width of the feature printed on the wafer. In addition, since the ABP is generally formed using an electron beam (e-beam), the ABP has a limitation that it cannot be formed in the outermost rectangular frame area of the absorption layer. The outermost rectangular frame of the absorption layer may include ground areas to which an e-beam exposure apparatus is grounded.

In the EUV mask 100 according to an embodiment of the present inventive concept, the defect avoidance pattern DAP may be formed in the non-transfer area NPA. Accordingly, the defect avoidance pattern DAP may not be transferred to the wafer in the EUV exposure process, and may also have a size equal to or greater than the minimum line width defined by the resolution of the EUV exposure apparatus. For example, the defect avoidance pattern DAP may not be limited to the resolution of the EUV exposure apparatus. Furthermore, in the EUV mask 100 according to an embodiment of the present inventive concept, the defect avoidance pattern DAP may be formed through not only an exposure process using an e-beam, but also an exposure process using a laser beam, a repair process using a laser beam, electron beam, or nano-machining, an imprint process, or a directed self-assembly (DSA) process. In addition, the defect avoidance pattern DAP may be formed through a single patterning process or a multiple patterning process such as, for example, double patterning or quadruple patterning. The single patterning or multiple patterning may be performed through the exposure process using the laser beam or electron beam, the repair process using a laser beam, electron beam, or nano-machining, the imprint process, or the DSA process. In other words, the defect avoidance pattern DAP will not be transferred to the wafer and may have a size not limited to a size smaller that the resolution limit of EUV exposure, and thus, may be formed in a process separated from the e-beam exposure process of forming the absorption patterns on the EUV mask.

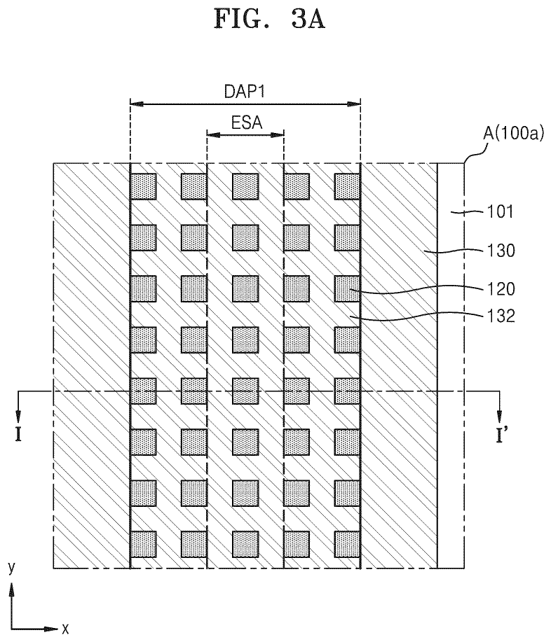

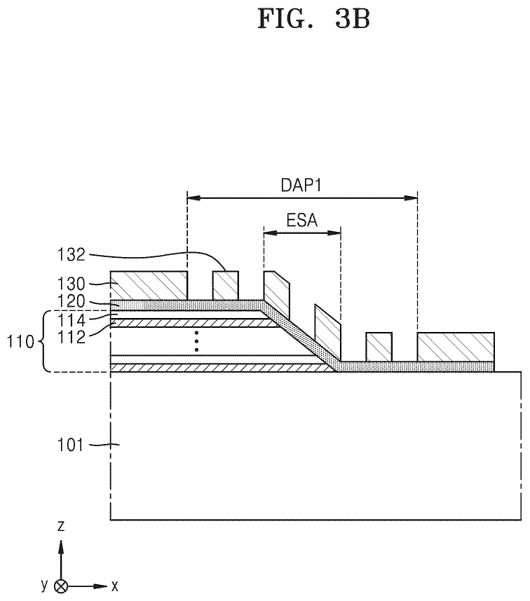

Referring to FIGS. 1, 3A, and 3B, an EUV mask 100a according to an embodiment of the present inventive concept may be different from the EUV mask 100 of FIG. 2A in the structure of a defect avoidance pattern DAP1. For example, in the EUV mask 100a according to an embodiment of the present inventive concept, the defect avoidance pattern DAP1 may have a rectangular frame or a rectangular ring shape, in plan view, surrounding along four sides of the EUV mask 100a, similar to the defect avoidance pattern DAP of the absorption layer 130 of the EUV mask 100 of FIG. 2A. For example, the defect avoidance pattern DAP1 may have a rectangular ring shape located at and surrounding along the outer portion of the EUV mask 100a. For example, the defect avoidance pattern DAP1 may have a rectangular ring shape located at the outer portion of the EUV mask 100 to surround the central portion of the EUV mask 100a. The central portion may include absorption patterns in the EUV finished mask.

In the EUV mask 100a according to an embodiment of the present inventive concept, defect avoidance pattern DAP1 may have a plurality of fine holes penetrating the absorption layer 130. The plurality of fine holes may be arranged in a two-dimensional array structure in the defect avoidance pattern DAP1. The fine holes may be defined by the lattice lines 132 of the absorption layer 130, and a horizontal cross section of each of the fine holes may have a rectangular shape, as shown in FIG. 3A. However, the shape of the horizontal cross section of the fine hole is not limited to a rectangular shape. For example, according to an embodiment of the present inventive concept, the horizontal cross section of the fine hole may have various shapes such as, for example, a circle, an ellipse, and a polygon other than a rectangle. Since the defect avoidance pattern DAP1 includes a plurality of fine holes arranged in a two-dimensional array structure, the defect avoidance pattern DAP1 may have an array pattern structure having a rectangular ring shape.

The defect avoidance pattern DAP1 may open the edge slope area ESA through the array pattern structure. However, the edge slope area ESA may be opened only in the fine holes, and may not be opened in the lattice lines 132 of the absorption layer 130 defining the fine holes. For example, the edge slope area ESA may only be exposed to the outside through the fine holes.

In the EUV mask 100a according to an embodiment of the present inventive concept, the defect avoidance pattern DAP1 may have an area larger than that of the edge slope area ESA. Even in the EUV mask 100a according to an embodiment of the present inventive concept, the area of the defect avoidance pattern DAP1 may be defined on a plane parallel to the top surface of the substrate 101. The area of the defect avoidance pattern DAP1 may be defined by an outer edge of each of the outermost fine holes. For example, as shown in FIG. 3A, the defect avoidance pattern DAP1 may roughly have a rectangular ring shape defined by the outer edge of each of the outermost fine holes, and the area of the rectangular ring may correspond to the area of the defect avoidance pattern DAP1. In addition, the area of the rectangular ring of the defect avoidance pattern DAP1 may be greater than the area of the edge slope area ESA. Furthermore, as shown in FIG. 3A, the edge slope area ESA may be positioned inside the defect avoidance pattern DAP1. Since the defect avoidance pattern DAP1 has an array pattern structure including a plurality of fine holes, the edge slope area ESA may be opened only in the fine holes. For example, the fine holes of the defect avoidance pattern DAP1 may expose the portion of the capping layer 120 corresponding to the edge slope area ESA. As shown in FIG. 3A or FIG. 3B, the edge slope area ESA may be positioned in the central portion of the defect avoidance pattern DAP1 in the X direction. However, the present inventive concept is not limited thereto.

The fine holes in the defect avoidance pattern DAP1 may have a very small size. The size of the fine holes may be defined as a width, a diameter, a minor axis, and the like. In other words, when the horizontal cross section of the fine hole is polygonal, the size of the fine hole may be defined as a width between opposite sides. In addition, the horizontal cross section of the fine hole is circular, the size of the fine hole may be defined as a diameter. When the horizontal cross section of the fine hole is elliptical, the size of the fine hole may be defined as a minor axis. However, the size of the fine hole is not limited to the above definitions.

The size of the fine hole may be, e.g., about 1 μm or less. For example, in the EUV mask 100a according to an embodiment of the present inventive concept, the horizontal cross section of the fine hole may be rectangular, and the width of the fine hole may be equal to or less than about 1 μm. However, the width of the fine hole is not limited to the aforementioned numerical range. The fine holes may be arranged in a two-dimensional array structure in the defect avoidance pattern DAP1. In other words, in FIG. 3A, the fine holes may be arranged at regular intervals or pitches in the X and Y directions in the defect avoidance pattern DAP1. For example, the fine holes may have a distance of about 4 μm or less from the fine holes adjacent to each other in the X and Y directions. In addition, when the fine holes have a width of about 1 μm or less, the fine holes may be arranged with a pitch of about 5 μm or less in the X and Y directions. However, the interval or pitch of the fine holes is not limited to the above numerical ranges. When the defect avoidance pattern DAP1 has a width of about 1500 μm in the X direction and the fine holes have a pitch of about 5 μm, about 300 fine holes may be arranged in the defect avoidance pattern DAP1 in the X direction. However, since the area of the defect avoidance pattern DAP1 and the width and pitch of the fine holes may be variously changed, the number of fine holes arranged in the defect avoidance pattern DAP1 is not limited to the above values. In the EUV mask 100a according to an embodiment of the present inventive concept, since the fine holes of the defect avoidance pattern DAP1 that open the edge slope area ESA are formed, the hydrogen (H₂) gas may be discharged through the fine holes of the defect avoidance pattern DAP1 to effectively prevent the blister defects.

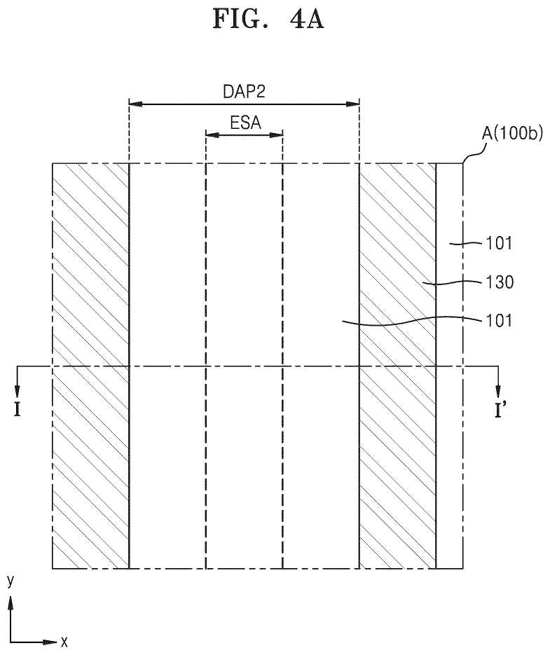

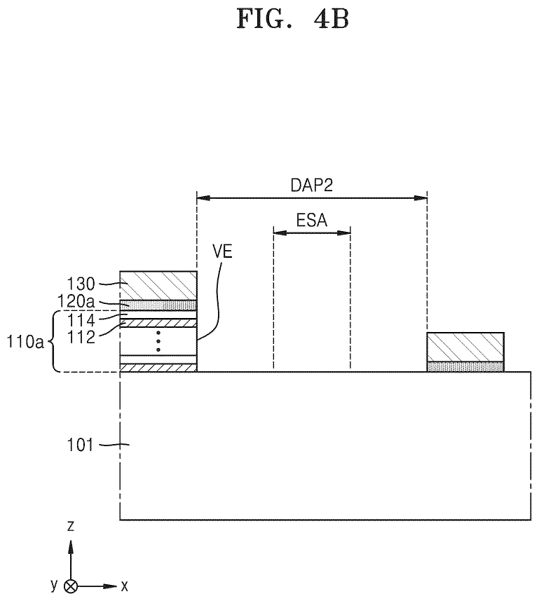

Referring to FIGS. 1, 4A, and 4B, an EUV mask 100b according to an embodiment of the present inventive concept may be different from the EUV mask 100 of FIG. 2A in the structure of a defect avoidance pattern DAP2. For example, in the EUV mask 100b according to an embodiment of the present inventive concept, the defect avoidance pattern DAP2 may have a rectangular frame or a rectangular ring shape, in plan view, surrounding along four sides of the EUV mask 100b, similar to the defect avoidance pattern DAP of the EUV mask 100 of FIG. 2A. For example, the defect avoidance pattern DAP2 may have a rectangular ring shape located at and surrounding along the outer portion of the EUV mask 100b. For Example, the defect avoidance pattern DAP2 may have a rectangular ring shape located at the outer portion of the EUV mask 100b to surround the central portion of the EUV mask 100b. The central portion may include absorption patterns in the EUV finished mask.

In the EUV mask 100b according to an embodiment of the present inventive concept, as shown in FIG. 4B, the defect avoidance pattern DAP2 may have a shape penetrating an absorption layer 130, a capping layer 120a, and a reflective multilayer 110a in a vertical direction. For example, the defect avoidance pattern DAP2 may open the top surface of the substrate 101. For example, the top surface of the substrate 101 may be exposed to the outside through the defect avoidance pattern DAP2. In addition, the defect avoidance pattern DAP2 having a rectangular ring shape may be integrally connected. Therefore, in the EUV mask 100b according to an embodiment of the present inventive concept, the defect avoidance pattern DAP2 may have a single pattern structure in the form of a rectangular ring.

Since the defect avoidance pattern DAP2 has a structure in which the top surface of the substrate 101 is opened, the edge slope area ESA and the corresponding portion of the capping layer 120a may be removed by forming the defect avoidance pattern DAP2. In other words, in the EUV mask 100b according to an embodiment of the present inventive concept, the reflective multilayer 110a may not include the edge slope area ESA, and the capping layer 120a may not include a portion corresponding to the edge slope area ESA. Instead, a vertical end VE may be formed at edges, i.e., outer edge portions, of the reflective multilayer 110a and the capping layer 120a. In FIGS. 4A and 4B, for comparison with other embodiments, the edge slope area ESA before the defect avoidance pattern DAP2 is formed is shown. As shown in FIG. 4B, the reflective multilayer 110a may include the vertical end VE, and the absorption layer 130 may include a first portion (which may also be referred to as a first absorption layer) covering a portion of the reflective multilayer 110a and a second portion (which may also be referred to as a second absorption layer) covering a portion of the substrate 101 outside the reflective multilayer 110a. The defect avoidance pattern DAP2 may be positioned between the first portion and the second portion of the absorption layer 130, and may open a portion of the substrate 101 between the vertical end VE and the second portion of the absorption layer 130. In addition, in the EUV mask 100b according to an embodiment of the present inventive concept, the capping layer 120a may be separated into an inner capping layer portion and an outer capping layer portion with the defect avoidance pattern DAP2 positioned therebetween since it has a structure in which the defect avoidance pattern DAP2 opens the top surface of the substrate 101. The inner capping layer portion (which may also be referred to as a first capping layer) may cover a top surface of the reflective multilayer 110a and the outer capping layer portion (which may also be referred to as a second capping layer) may be spaced apart from the vertical end VE and covering a top surface of an outer portion of the substrate 101, and the defect avoidance pattern DAP2 may open a portion of the substrate 101 between the vertical end VE and the outer capping layer portion. The first absorption layer may cover the first capping layer, and the second absorption layer may cover the second capping layer. The defect avoidance pattern DAP2 may open a portion of the substrate 101 between the vertical end VE and the second capping layer. As a result, the EUV mask 100b according to an embodiment may prevent blister defects by removing the edge slope area ESA through the defect avoidance pattern DAP2.

Referring back to FIGS. 1, 2A and 2B, the capping layer 120 may include a first capping layer and a second capping layer. The reflective multilayer 110 may include the edge slope area ESA, the first capping layer may cover a top surface of the reflective multilayer 110 and an inclined surface of the edge slope area ESA, and the second capping layer extending from the first capping layer may cover a portion of the substrate 101 outside the edge slope area ESA toward the edge of the substrate 101. The first absorption layer may cover a portion of the first capping layer on the top surface of the reflective multilayer 110, and the second absorption layer may be spaced apart from the first capping layer and may cover an outer portion of the second capping layer. The defect avoidance pattern DAP may open a portion of the capping layer 120 between the first absorption layer and the second absorption layer.

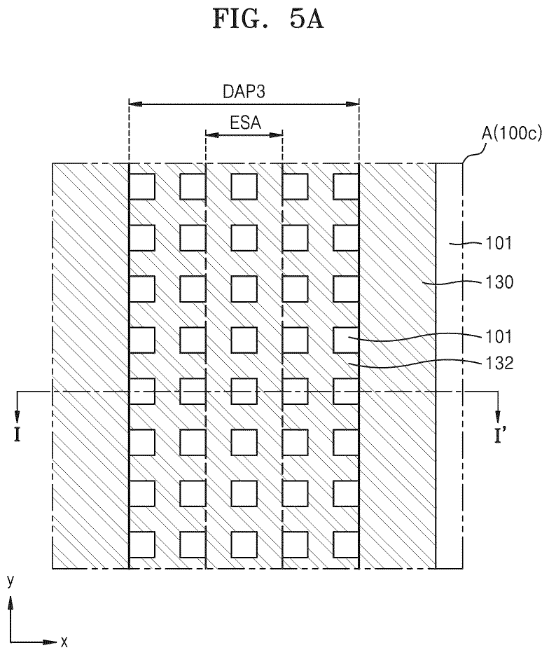

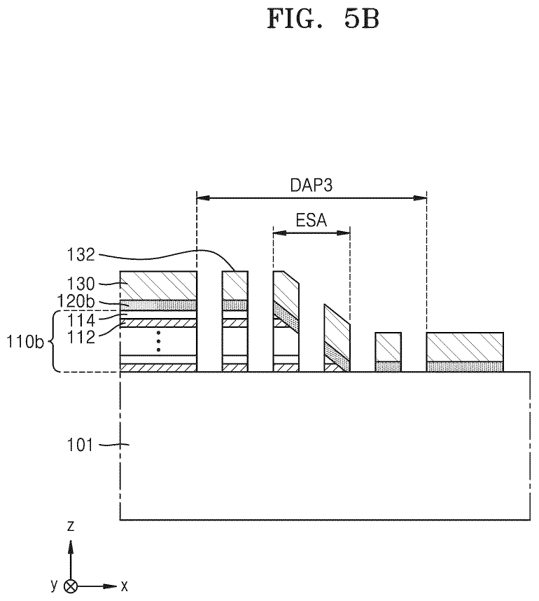

Referring to FIGS. 1, 5A, and 5B, an EUV mask 100c according to an embodiment of the present inventive concept may be different from the EUV mask 100b of FIG. 4A in the structure of a defect avoidance pattern DAP3. For example, in the EUV mask 100c according to an embodiment of the present inventive concept, the defect avoidance pattern DAP3 may have a rectangular frame or a rectangular ring shape, in plan view, surrounding along four sides of the EUV mask 100c, similar to the defect avoidance pattern DAP2 of the EUV mask 100b of FIG. 4A. For example, the defect avoidance pattern DAP3 may have a rectangular ring shape located at and surrounding along the outer portion of the EUV mask 100c. For Example, the defect avoidance pattern DAP3 may have a rectangular ring shape located at the outer portion of the EUV mask 100 to surround the central portion of the EUV mask 100c. The central portion may include absorption patterns in the EUV finished mask.

In the EUV mask 100c according to an embodiment of the present inventive concept, the defect avoidance pattern DAP3, similar to the EUV mask 100a of FIG. 3A, may have a plurality of fine holes. In the EUV mask 100c according to an embodiment of the present inventive concept, the fine holes of the defect avoidance pattern DAP3 may pass through the absorption layer 130, the capping layer 120b, and the reflective multilayer 110b. The plurality of fine holes may be arranged in a two-dimensional array structure in the defect avoidance pattern DAP3. The fine holes may be defined by the lattice lines 132 of the absorption layer 130 and the corresponding lower lattice lines of the capping layer 120b and the reflective multilayer 110b, and a horizontal cross section of each of the fine holes may have a rectangular shape, as shown in FIG. 5A. However, the shape of the horizontal cross section of the fine hole is not limited to a rectangular shape. For example, according to an embodiment of the present inventive concept, the horizontal cross section of the fine hole may have various shapes such as, for example, a circle, an ellipse, and a polygon other than a rectangle. In the EUV mask 100c according to an embodiment of the present inventive concept, since the defect avoidance pattern DAP3 includes a plurality of fine holes arranged in a two-dimensional array structure, the defect avoidance pattern DAP3 may have an array pattern structure having a rectangular ring shape.

The defect avoidance pattern DAP3 may open a portion of the top surface of the substrate 101 through the array pattern structure. However, the top surface of the substrate 101 may be opened only in the fine holes, but may not be opened in the lattice lines 132 defining the fine holes and the corresponding lower lattice lines. For example, the top surface of the substrate 101 may only be exposed to the outside through the fine holes of the defect avoidance pattern DAP3.

The defect avoidance pattern DAP3 of the EUV mask 100c according to an embodiment of the present inventive concept may be similar to the defect avoidance pattern DAP2 of the EUV mask 100b of FIG. 4A in that the top surface of the substrate 101 is opened. In addition, the defect avoidance pattern DAP3 of the EUV mask 100c according to an embodiment of the present inventive concept may be similar to the defect avoidance pattern DAP1 of the EUV mask 100a of FIG. 3A in a structure having fine holes. Accordingly, a detailed description of the defect avoidance pattern DAP3 is omitted. Since the defect avoidance pattern DAP3 of the EUV mask 100c opens the top surface of the substrate 101 through fine holes, the edge slope area ESA and the corresponding portion of the capping layer 120b may maintain a structure including fine holes. In the EUV mask 100c according to an embodiment of the present inventive concept, since the fine holes of the defect avoidance pattern DAP3 that open the top surface of the substrate 101 are formed, the hydrogen (H₂) gas may be discharged through the fine holes of the defect avoidance pattern DAP3 to effectively prevent the blister defects.

FIGS. 6A to 6E are a plan view, a cross-sectional view, and pictures showing the defects of an EUV mask of a comparative example. FIG. 6B is a scanning electron microscope (SEM) picture showing an enlarged portion B of FIG. 6A, FIG. 6C is a cross-sectional view taken along line II-II′ of FIG. 6B, FIG. 6D is an SEM picture showing fragments (defects) caused by blister bursting of the EUV mask of a comparative example, and FIG. 6E is an SEM picture showing the result of transferring the patterns/defects of the EUV mask of a comparative example to the wafer.

Referring to FIGS. 6A to 6E, an EUV mask BM of the comparative example may include a transfer area PA in a central portion thereof and a non-transfer area NPA in an outer portion thereof. A portion of the edge slope area ESA may be positioned in a portion B of FIG. 6A. FIG. 6B which is the enlarged SEM picture of the portion B shows that a plurality of blister defects may appear in the edge slope area ESA. FIG. 6B which is the enlarged SEM picture of the portion B shows that blister defects may appear along the X direction, corresponding to the edge slope area ESA according to FIG. 6C which is a cross-sectional view showing an EUV mask.

In the cross-sectional view of FIG. 6C, SOA may refer to an open area of an edge portion of the substrate SUB. For example, a top surface of the substrate SUB at SOA may be exposed. A first width W1 of the SOA of a substrate SUB may be, e.g., about 1.0 mm or more. In addition, the distance from the outermost portion of the edge slope area ESA to the edge SE of the substrate SUB, i.e., first distance D1, may be about 2 mm or more. However, the first width W1 of the SOA and the first distance D1 are not limited to the above numerical ranges. In addition, as described with reference to FIG. 1, the ABP on the right side of the absorption layer ABs shown in FIG. 6C may correspond to the blister avoidance pattern (i.e., anti-blister pattern) formed in portions of the transfer area PA and the non-transfer area NPA of the absorption layer ABs. The ABP may be formed in a size smaller than a minimum line width defined by the resolution of the EUV process.

The SEM picture of FIG. 6D shows enlarged defects BD of fragments caused by blister bursting of the EUV mask BM of the comparative example. As described above, when the hydrogen atom (H*) concentration is high enough, bubbles of gaseous hydrogen (H₂) compounds may be formed to lift the capping layer CL and/or the absorption layer ABs above these bubbles. The capping layer CL and/or the absorption layer ABs may then burst, thus releasing the hydrogen (H₂) gas, leading to the formation of the blister defects BD as shown in FIG. 6D. The wafer transfer pattern may be partially covered by the fragments due to blister bursting. FIG. 6E shows a pattern on a wafer WF transferred through EUV exposure using the EUV mask BM of the comparative example having the blister defects BD. Due to the blister defects BD, defects may repeatedly appear in the pattern on the wafer WF. In addition, the blister defects on the EUV mask may not only cause pattern defects on the wafer, but also contaminate an EUV scanner, causing secondary contamination of subsequent wafers entering the EUV scanner.

In the edge slope area ESA, the interface between the reflective multilayer ML and the capping layer CL may be relatively less adhesive, and, accordingly, oxidation may be promoted in the edge slope area ESA to increase the oxide layer. For example, the oxide layer increases by up to 24% in the edge slope area ESA, compared to other areas. Accordingly, it may be analyzed that the blister defects BD increase in the edge slope area ESA. However, in the EUV masks 100, 100a to 100c according to an embodiment of the present inventive concept, the blister defects of the edge slope area ESA may be effectively prevented by forming the defect avoidance pattern DAP, DAP1 to DAP3 opening the edge slope area ESA or a portion of the top surface of the substrate 101 corresponding to the edge slope area ESA.

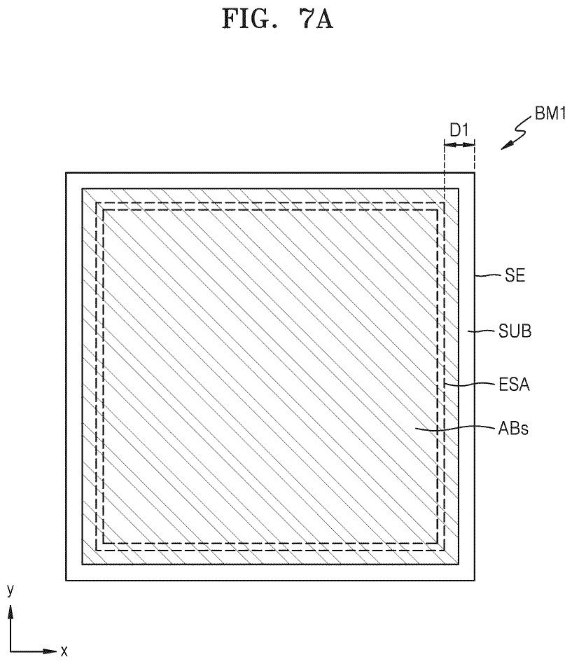

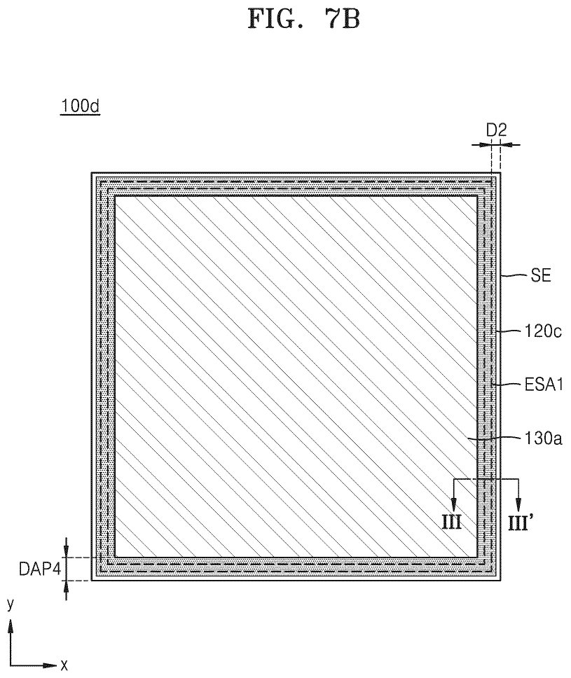

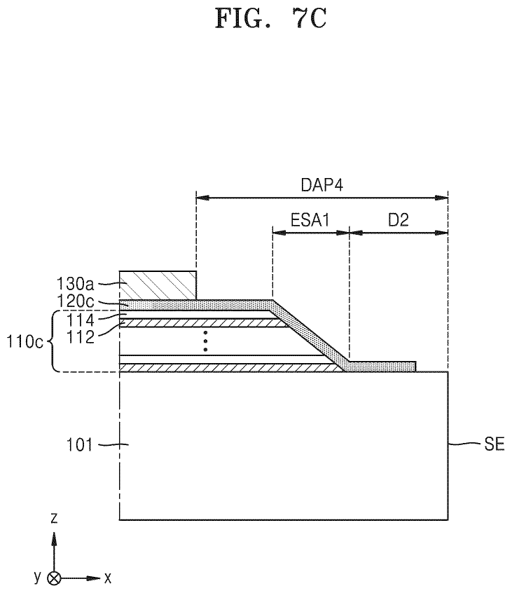

FIGS. 7A to 7C are a plan view of an EUV mask of a comparative example, a plan view and a cross-sectional view of an EUV mask according to an embodiment of the present inventive concept. FIG. 7C is a cross-sectional view of an EUV mask taken along line III-III′ of FIG. 7B. The details already described with reference to FIGS. 1 to 6E are briefly described or omitted.

Referring to FIG. 7A, in an EUV mask BMI of a comparative example, the edge slope area ESA may have a first distance D1 from an edge SE of a substrate SUB, where the first distance D1 may be about 2 mm or more. For example, in the EUV mask BMI of the comparative example, the first distance D1 may be about 2.8 mm. Since the EUV mask BMI does not have defect avoidance patterns, the blister defects may be formed on the EUV mask BMI similar to the EUV mask BM described above and may cause blister defects BD on wafer. Accordingly, to prevent blister defects in the edge slope area ESA, as in the EUV masks 100, 100a to 100c of FIGS. 2A, 3A, 4A, and 5A, separate defect avoidance patterns DAP, DAP1 to DAP3 may be required.

Referring to FIGS. 7B and 7C, in an EUV mask 100d according to an embodiment of the present inventive concept, an edge slope area ESA1 may have a second distance D2 from the edge SE of the substrate 101, where the second distance D2 may be about 2 mm or less. For example, an outermost portion of the edge slope area ESA1 may have a distance of less than about 2 mm from the edge SE of the substrate 101. For example, in the EUV mask 100d according to an embodiment of the present inventive concept, the second distance D2 may be about 1.1 mm. However, the second distance D2 is not limited to the aforementioned numerical value. For example, the second distance D2 may be about 1 mm or less.

As the edge slope area ESA1 is positioned adjacent to the edge SE of the substrate 101, the area of a reflective multilayer 110c may increase as much as the edge slope area ESA1 moves. A capping layer 120c may also be changed to correspond to a change in the shape of the reflective multilayer 110c. In other words, the capping layer 120c may cover the edge slope area ESA1 of the reflective multilayer 110c, and may extend from the edge slope area ESA1 to cover the top surface of the substrate 101. As shown in FIG. 7C, the capping layer 120c may not cover the outermost portion of the substrate 101. For example, a top surface of the outermost portion of the substrate 101 may be exposed. However, according to an embodiment of the present inventive concept, the capping layer 120c may cover the outermost portion of the substrate 101.

In the EUV mask 100d according to an embodiment of the present inventive concept, a defect avoidance pattern DAP4 may open both the edge slope area ESA1 and the outside of the edge slope area ESA1 toward the edge SE of the substrate 101. For example, an absorption layer 130a may not be positioned outside the edge slope area ESA1 toward the edge SE of the substrate 101. For example, the defect avoidance pattern DAP4 may open an entire portion of the substrate 101 outside the edge slope area ESA1 toward the edge SE of the substrate 101 when the capping layer 120c is not present or only covers the top surface of reflective multilayer 110c. In an embodiment of the present inventive concept, the capping layer 120c may include a first capping layer covering a top surface of the reflective multilayer 110c and an inclined surface of the edge slope area ESA1, and a second capping layer extending from the first capping layer and covering a portion of the substrate 101 outside the edge slope area ESA1 toward the edge SE of the substrate 101. The absorption layer 130a may be disposed on a portion of the first capping layer covering the top surface of the reflective multilayer 110c, and the defect avoidance pattern DAP4 may open a portion of the first capping layer covering the inclined surface of the edge slope area ESA1 and an entirety of the second capping layer.

In the EUV mask 100d according to an embodiment of the present inventive concept, the defect avoidance pattern DAP4 may not be formed through a separate patterning process, but through at least one of essential and/or common processes during the EUV mask manufacturing process, e.g., edge trimming processes. The edge trimming process may include various processes of exposing the edge portion of the substrate 101. For example, the edge trimming process may include, for example, a mask edge removal (MER) process, a multi-layer etch (MLE) process, and a fiducial mark (FM)/arcing robust mark (ARM) process. The MER process is a process of removing photoresist (PR) from an edge portion of an EUV mask. In the MER process, an edge portion of an absorption layer may be removed to expose a top surface of an edge portion of a capping layer. In other words, after the MER process, the capping layer 120c and the reflective multilayer 110c may remain. The MLE process is a process of etching a reflective multilayer, and a top surface of an edge portion of a substrate may be exposed through the MLE process. As can be seen from the terminology, in the MLE process, the edge portions of the reflective multilayer and the capping layer may also be removed. For example, after the MLE process, the absorption layer 130a, the capping layer 120c, and the reflective multilayer 110c may be removed, and thus, the top surface of the substrate 101 may be exposed. The FM/ARM process may refer to a process of removing the absorption layer and the capping layer of the edge portion of the EUV mask to prevent arcing of the EUV mask in a process of forming the FM. In the FM/ARM process, the edge portion of the reflective multilayer may or may not be removed.

The FM may be used to detect defects in mask defect avoidance (MDA), and may generally be arranged in a cross-shaped pattern at four vertices of the absorption layer. The MDA may refer to a technique of avoiding defects by using an absorption layer when defects that cannot be repaired exist in the EUV mask. For example, the MDA may refer to a technique of avoiding defects by preventing transfer of defects to a wafer by linearly moving or rotating the EUV mask so that the defects are located in a portion where the absorption layer exists, i.e., in a dark pattern portion. For example, in the MDA, the defects may be relocated to non-printable areas, such as under the absorber patterns in the device layout, based on the information of the defects from the blank inspection. Thus, alignment through the FM between blank defects coordinates and e-beam writing is the key process for the precise control of the MDA. The MDA may also refer to multilayer defect avoidance.

In the EUV mask 100d according to an embodiment of the present inventive concept, the defect avoidance pattern DAP4 may be formed through at least one of essential/common edge trimming processes in the EUV mask manufacturing process, thereby effectively avoiding or preventing blister defects without a separate additional exposure/patterning process. Therefore, the EUV mask 100d according to an embodiment of the present inventive concept may contribute to optimization of the manufacturing process by preventing resource waste such as additional process/facility and time around time (TAT) loss, during the EUV mask manufacturing process.

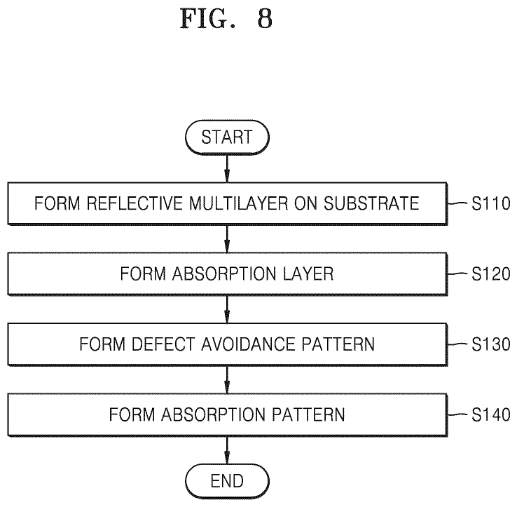

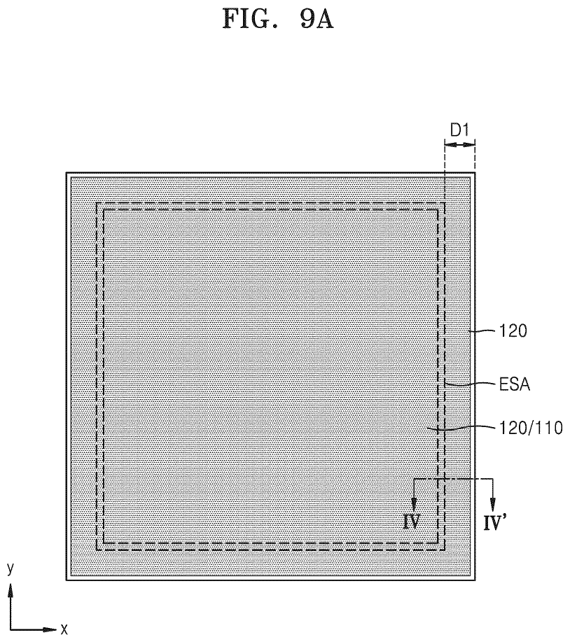

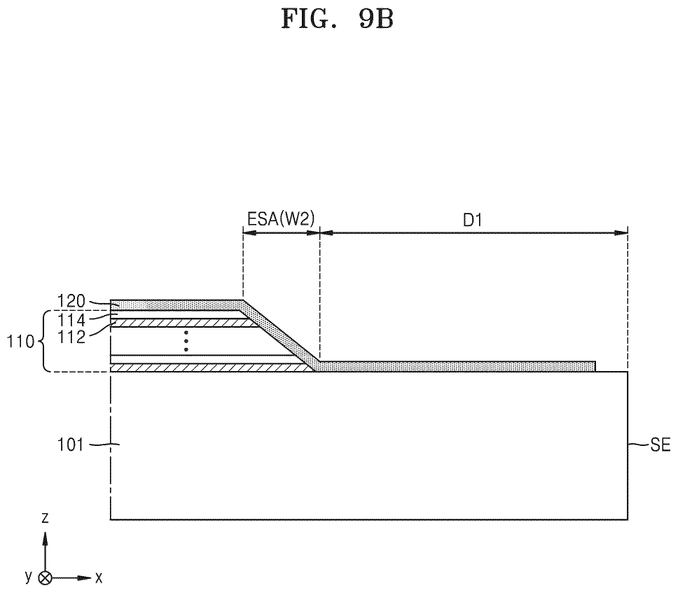

FIG. 8 is a flowchart schematically illustrating a process of a method of manufacturing the EUV mask of FIG. 1 according to an embodiment of the present inventive concept, and FIGS. 9A to 12B are plan views and cross-sectional views of an EUV mask corresponding to operations of the method of manufacturing the EUV mask of FIG. 8. FIGS. 9B, 10B, 11B, and 12B are cross-sectional views taken along lines IV-IV′ of FIGS. 9A, 10A, 11A, and 12A, respectively. Referring to FIGS. 1 to 2B, the details already described with reference to FIGS. 1 to 7C are briefly described or omitted.

Referring to FIGS. 8, 9A, and 9B, a method of manufacturing an EUV mask according to an embodiment of the present inventive concept includes forming a reflective multilayer 110 on a substrate 101 (S110). The substrate 101 may include an LTEM. For example, the substrate 101 may include glass, Si, quartz, or the like. The low thermal expansion quality of the substrate 101 is a feature adopted to prevent the mask from warping or otherwise distorting the image, and the LTEM may be a titanium oxide (TiO₂) doped silicon oxide (SiO₂) glass. The substrate 101 may have a larger size than the reflective multilayer 110.

An edge slope area ESA may be formed at an outer edge portion of the reflective multilayer 110. A distance from the outermost portion of the edge slope area ESA to the edge SE of the substrate 101, i.e., first distance D1, may be about 2 mm or more. However, the first distance D1 is not limited to the above numerical range. As shown in FIG. 9A, in plan view, the edge slope area ESA may have a rectangular ring shape. In addition, the edge slope area ESA may have a second width W2 in the width direction, e.g., X direction in FIG. 9B. The second width W2 may be, e.g., about 0.5 mm. However, the second width W2 of the edge slope area ESA is not limited to the above value.

The reflective multilayer 110 may have a multilayer structure in which dozens of alternating layers of two different materials are stacked. The reflective multilayer 110 may include a first material layer 112 that is a low refractive index layer and a second material layer 114 that is a high refractive index layer. For example, the first material layer 112 may include Mo, and the second material layer 114 may include Si. For example, the reflective multilayer 110 may be a Mo/Si multilayer reflective film with layers of Mo and Si alternately stacked for about 40 to 60 cycles. However, the materials of the first material layers 112 and the second material layers 114 are not limited to the above materials.

In the operation S110 of forming the reflective multilayer 110, a capping layer 120 may be further formed on the top surface of the reflective multilayer 110. The capping layer 120 may cover the top surface of the reflective multilayer 110, the inclined surface of the edge slope area ESA, and the top surface of the substrate 101. As shown in FIG. 9B, the capping layer 120 may cover outer portion of the substrate 101, but may not cover the outermost portion of the substrate 101. For example, a top surface of the outermost portion of the substrate 101 may be exposed. However, according to an embodiment of the present inventive concept, the capping layer 120 may cover the outermost portion of the substrate 101.

The capping layer 120 may be formed to prevent damage to the reflective multilayer 110 and surface oxidation of the reflective multilayer 110. In the method of manufacturing the EUV mask according to an embodiment of the present inventive concept, the capping layer 120 may cover the top surface of the second material layer 114 of Si to prevent the second material layer 114 from being oxidized. For example, the capping layer 120 may include Ru. Alternatively, the capping layer 120 may include an alloy of Ru. However, the material of the capping layer 120 is not limited to Ru or an alloy of Ru. The capping layer 120 may be optional. Accordingly, in an embodiment of the present inventive concept, the capping layer 120 may be omitted.

After the reflective multilayer 110 and the capping layer 120 are formed, a process of inspecting whether there is a defect in the reflective multilayer 110 may be performed. Such a defect inspection for the reflective multilayer 110 is referred to as an EUV blank mask inspection or, simply, a blank inspection. The blank inspection may be performed by scanning the reflective multilayer 110 or the capping layer 120 with a laser beam. The blank inspection with the laser beam may accurately identify the defect location, and obtain information of defect size and shape for defect mitigation. In addition, when the blank inspection starts, beam calibration may be performed at a beam calibration point.

Referring to FIGS. 8, 10A, and 10B, after the reflective multilayer 110 is formed, an absorption layer 130 is formed on the reflective multilayer 110 or the capping layer 120 (S120). For example, the absorption layer 130 may be formed on the capping layer 120, or may be formed on the reflective multilayer 110 when the capping layer 120 is omitted. The absorption layer 130 may be patterned, and thus, for example, the absorption layer 130 may be positioned on at least a portion of the reflective multilayer 110 or at least a portion of the capping layer 120. As described above, the absorption layer 130 may be divided into a central transfer area PA and a peripheral non-transfer area NPA. The absorption layer 130 may include a material that absorbs EUV rays. For example, the absorption layer 130 may include TaN, TaHf, TaHfN, TaBSi, TaBSiN, TaB, TaBN, TaSi, TaSiN, TaGe, TaGeN, TaZr, TaZrN, or combinations thereof. However, the material of the absorption layer 130 is not limited to the above materials.

In the operation S120 of forming the absorption layer 130, an edge trimming process of removing edge portions of the absorption layer 130 and the capping layer 120 may be performed. The edge trimming process may include, for example, an MLE process, and/or an FM/ARM process. Accordingly, as shown in FIG. 10B, the top surface of the edge portion of the substrate 101 may be exposed. After the edge trimming process, the first width W1 of the exposed edge portion of the substrate 101 may be, e.g., about 1.0 mm or more. According to an embodiment of the present inventive concept, the edge trimming process may be performed when forming an absorption pattern on the absorption layer 130. The absorption pattern may include open areas and non-open areas in the absorption layer 130 and may allow the EUV rays to pass through open areas of the absorption layer 130 and pass through the capping layer 120 to reach the reflective multilayer 110. Then, the EUV rays may be reflected by the reflective multilayer 110 and irradiated onto a wafer to be exposed.

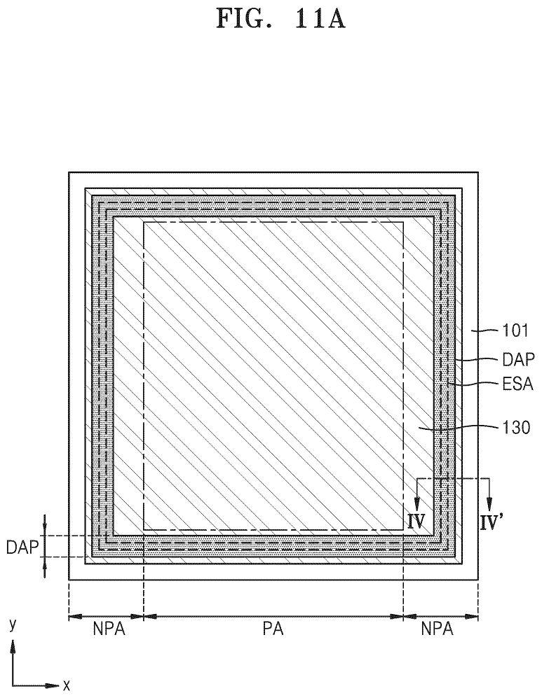

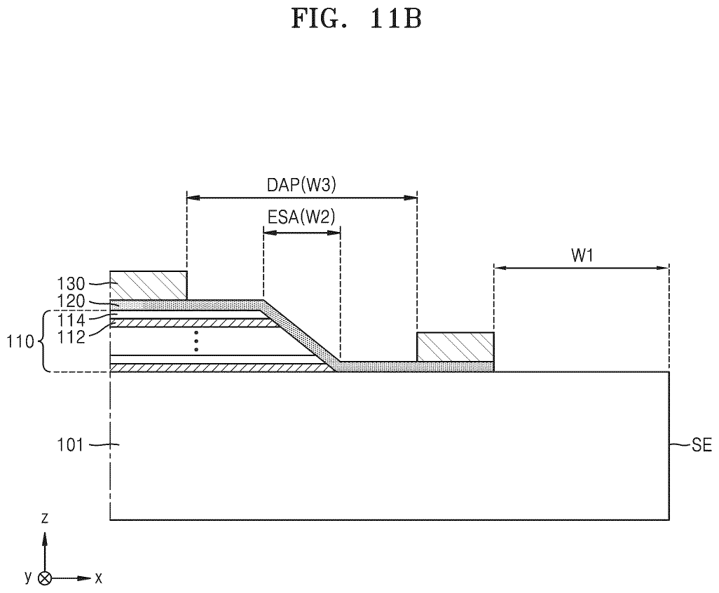

Referring to FIGS. 8, 11A, and 11B, after the absorption layer 130 is formed, the defect avoidance pattern DAP may be formed in the non-transfer area NPA of the absorption layer 130 (S130). As shown in FIG. 11A, the defect avoidance pattern DAP may be formed in a rectangular ring shape at edge portions of four sides of the absorption layer 130. In addition, the defect avoidance pattern DAP may have a shape penetrating the absorption layer 130 in a vertical direction. For example, the defect avoidance pattern DAP may expose the capping layer 120. The defect avoidance pattern DAP in the form of a rectangular ring may be integrally connected to have a single pattern structure. However, the defect avoidance pattern DAP is not limited thereto, and may have an array pattern structure, as in the EUV mask 100a of FIG. 3A. In addition, as in the EUV masks 100b and 100c of FIGS. 4A and 5A, a portion of the top surface of the substrate 101 may be opened by removing portions of the capping layer 120 and the reflective multilayer 110 corresponding to the edge slope area ESA. In the EUV mask 100b of FIG. 4B, a vertical end VE may be formed at edges, i.e., outer edge portions, of the reflective multilayer 110a and the capping layer 120a.

The defect avoidance pattern DAP may be formed through an exposure process using an electron beam or laser beam, a repair process using a laser beam, electron beam, or nano-machining, an imprint process, or a DSA process. In addition, the defect avoidance pattern DAP may be formed through a single patterning process or a multiple patterning process such as double patterning or quadruple patterning. Since the defect avoidance pattern DAP is formed in the non-transfer area NPA, it may not be transferred to the wafer in the EUV exposure process. Accordingly, the defect avoidance pattern DAP may have a size equal to or greater than a minimum line width defined by the resolution of the EUV exposure apparatus. For example, the defect avoidance pattern DAP may not be limited to the resolution of the EUV exposure apparatus. In other words, the defect avoidance pattern DAP will not be transferred to the wafer and may have a size not limited to a size smaller that the resolution limit of EUV exposure, and thus, may be formed in a process separated from the e-beam exposure process of forming the absorption patterns on the EUV mask.

The defect avoidance pattern DAP may open the edge slope area ESA of the reflective multilayer 110. The defect avoidance pattern DAP may have a larger area than the edge slope area ESA. For example, in FIG. 11B, the edge slope area ESA may have a second width W2 in the X direction, and the defect avoidance pattern DAP may have a third width W3 in the X direction. The third width W3 may be greater than the second width W2. For example, the third width W3 of the defect avoidance pattern DAP may be greater than the second width W2 of the edge slope area ESA in a width direction perpendicular to a longitudinal direction in which the defect avoidance pattern DAP extends. For example, when the longitudinal direction is Y direction, the width direction may be X direction, and when the longitudinal direction is X direction, the width direction may be Y direction. In addition, as shown in FIG. 11A or FIG. 11B, the edge slope area ESA may be positioned inside the defect avoidance pattern DAP. As shown in FIG. 11A or FIG. 11B, the edge slope area ESA in the X direction may be positioned in the central portion of the defect avoidance pattern DAP. However, according to an embodiment of the present inventive concept, the edge slope area ESA may be positioned to be biased to one side in the X direction, or may be positioned such that at least a portion thereof is open through the defect avoidance pattern DAP. The third width W3 may have a width twice or more than the second width W2, so that the edge slope area ESA may be completely open, but the present inventive concept is not limited thereto.

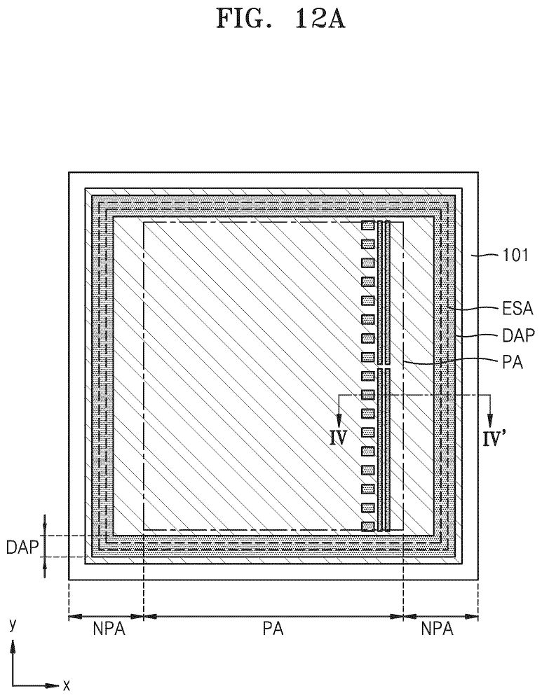

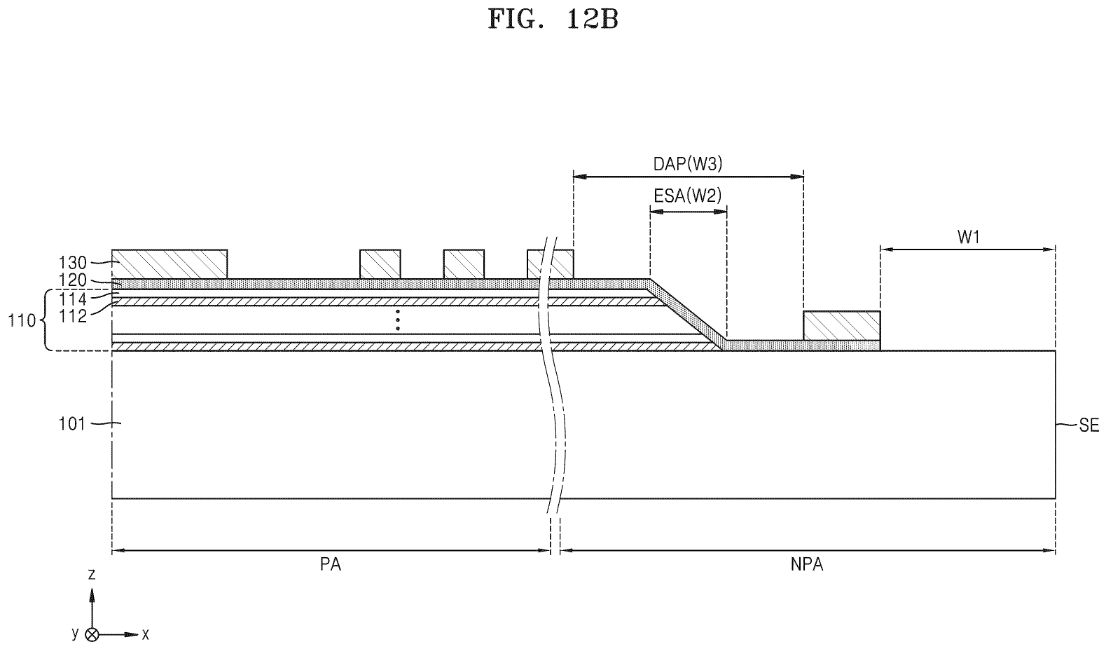

Referring to FIGS. 8, 12A, and 12B, an absorption pattern is formed on the absorption layer 130 (S140). The absorption pattern may be formed through an e-beam exposure process, but the present inventive concept is not limited thereto. The absorption pattern may include process patterns formed in the non-transfer area NPA of the absorption layer 130, and transfer patterns formed in the transfer area PA of the absorption layer 130. The transfer patterns may be transferred to a wafer through an EUV exposure process. By forming the absorption pattern on the absorption layer 130, the EUV mask 100 may be finished. The method of manufacturing the EUV mask according to an embodiment of the present inventive concept may prevent or minimize blister defects in the EUV mask 100 during the EUV exposure process by opening the edge slope area ESA through the defect avoidance pattern DAP.

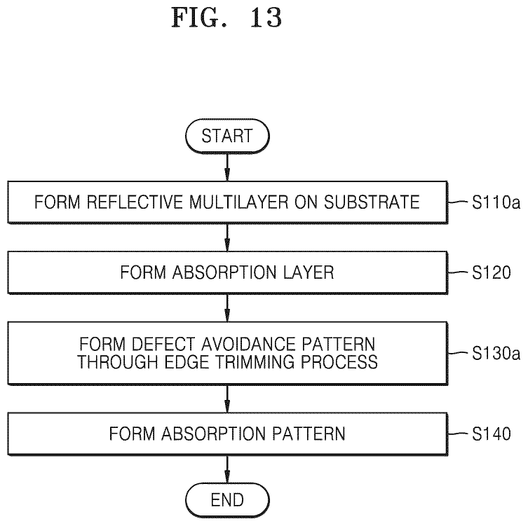

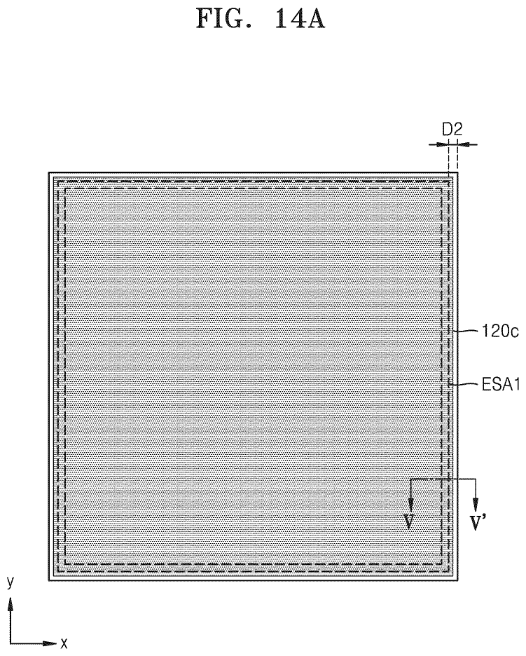

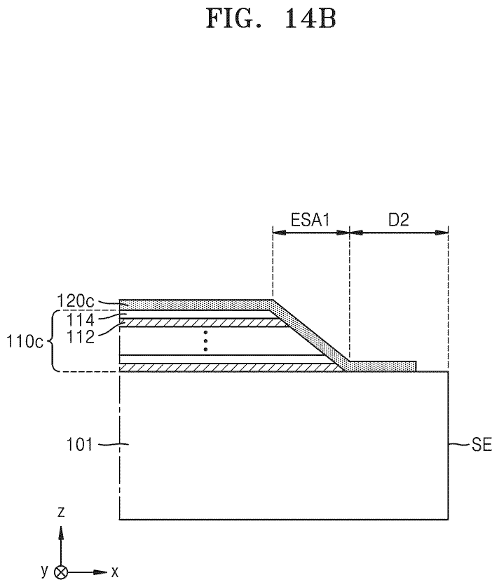

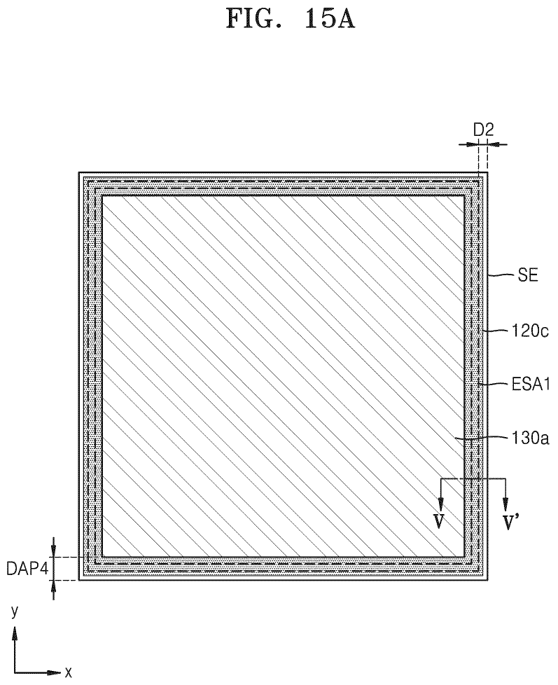

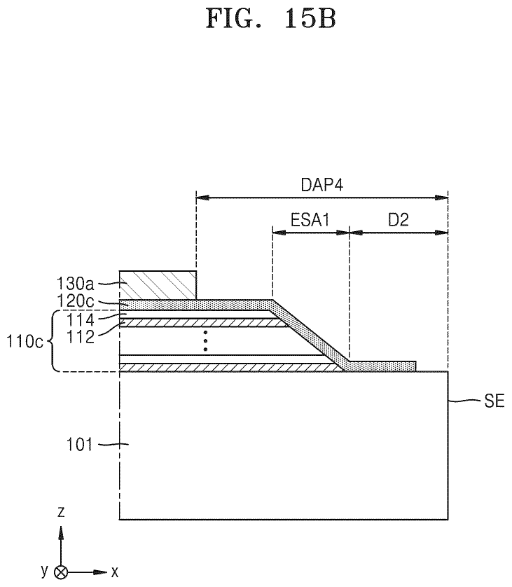

FIG. 13 is a flowchart schematically illustrating a method of manufacturing the EUV mask of FIG. 7B according to an embodiment of the present inventive concept, and FIGS. 14A to 15B are plan views and cross-sectional views of an EUV mask corresponding to operations of the method of manufacturing the EUV mask of FIG. 13. FIGS. 14B and 15B are cross-sectional views taken along lines V-V′ of FIGS. 14A and 15A, respectively. Referring to FIGS. 7B and 7C, details already described with reference to FIGS. 8 to 12B may be briefly described or omitted.

Referring to FIGS. 13, 14A, and 14B, the method of manufacturing the EUV mask according to an embodiment of the present inventive concept includes forming a reflective multilayer 110c on the substrate 101 (S110a). In the method of manufacturing the EUV mask according to an embodiment of the present inventive concept, except that the edge slope area ESA1 of the reflective multilayer 110c is formed closer to the edge SE of the substrate 101, the operation S110a of forming the reflective multilayer 110c may be substantially the same as the operation S110 of forming the reflective multilayer 110 in the method of manufacturing the EUV mask of FIG. 8.

In the method of manufacturing the EUV mask of FIG. 8, the edge slope area ESA of the reflective multilayer 110 may be formed at a first distance D1 from the edge SE of the substrate 101 (see FIG. 9B). The first distance D1 may be equal to or greater than about 2 mm, e.g., about 2.8 mm. On the contrary, in the method of manufacturing the EUV mask according to an embodiment of the present inventive concept, the edge slope area ESA1 of the reflective multilayer 110c may be formed at a second distance D2 from the edge SE of the substrate 101 (see FIG. 14B). The second distance D2 may be less than about 2 mm, e.g., about 1.1 mm. However, the first distance D1 and the second distance D2 are not limited to the above numerical ranges.

Other details related to the operation S110a of forming the reflective multilayer 110c are the same as those related to the operation S110 of forming the reflective multilayer 110 in the method of manufacturing the EUV mask of FIG. 8. In addition, the capping layer 120c may also be changed to correspond to the change in the shape of the reflective multilayer 110c. In other words, the capping layer 120c may cover the edge slope area ESA1 of the reflective multilayer 110c, and may extend from the edge slope area ESA1 to cover the top surface of the substrate 101. As shown in FIG. 14B, the capping layer 120c may not cover the outermost portion of the substrate 101. For example, a top surface of the outermost portion of the substrate 101 may be exposed. However, according to an embodiment of the present inventive concept, the capping layer 120c may cover the outermost portion of the substrate 101.

Referring to FIG. 13, after the reflective multilayer 110c is formed, an absorption layer 130 is formed on the reflective multilayer 110c or the capping layer 120c (S120). The operation S120 of forming the absorption layer 130 with reference to FIG. 13 is the same as the operation S120 of forming the absorption layer 130 in the method of manufacturing the EUV mask of FIG. 8. Before the operation S120 of forming the absorption layer 130 after forming the reflective multilayer 110c, the EUV blank mask inspection may be performed. The EUV blank mask inspection may be performed by scanning the reflective multilayer 110c or the capping layer 120c with a laser beam. The EUV blank mask inspection with the laser beam may accurately identify the defect location, and obtain information of defect size and shape for defect mitigation.

Referring to FIGS. 13, 15A, and 15B, the defect avoidance pattern DAP4 is formed through an edge trimming process (S130a). The edge trimming process may include, for example, a MER process, an MLE process, and/or an FM/ARM process. Each process is as described with respect to the EUV mask 100d of FIGS. 7B and 7C. When the MLE process or the FM/ARM process is performed as the edge trimming process, the capping layer 120 may also be removed to expose the top surface of the edge portion of the substrate 101. In contrast, when the MER process is performed, the capping layer 120 may be maintained to cover the top surface of the edge portion of the substrate 101. Accordingly, in FIG. 15B, the result of the edge trimming process performed through the MER process is shown.

Referring to FIG. 13, after the defect avoidance pattern DAP4 is formed, an absorption pattern on the absorption layer 130 is formed (S140). The operation S140 of forming the absorption pattern with reference to FIG. 13 is the same as the operation S140 of forming the absorption pattern in the method of manufacturing the EUV mask of FIG. 8.

In the method of manufacturing the EUV mask according to an embodiment of the present inventive concept, by forming the defect avoidance pattern DAP4 through at least one of essential/common edge trimming processes in the EUV mask manufacturing process, blister defects may be effectively avoided or prevented without an additional exposure/patterning process. Therefore, the method of manufacturing the EUV mask according to an embodiment of the present inventive concept may contribute to optimization of the manufacturing process by preventing resource waste such as additional process/facility and TAT loss during the EUV mask manufacturing process.

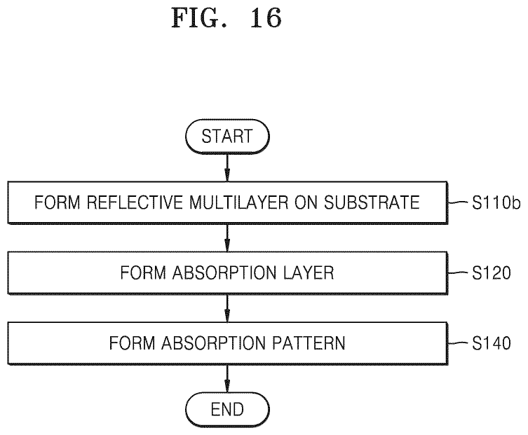

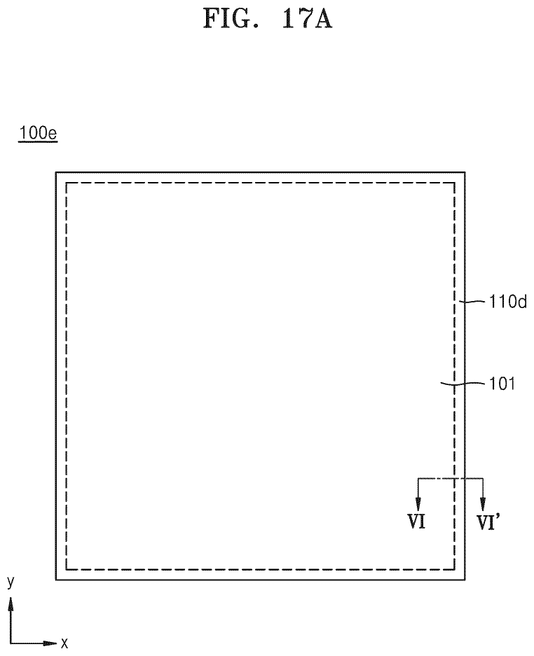

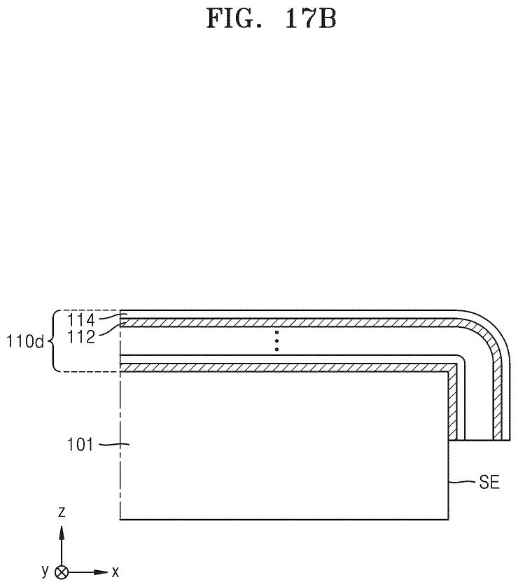

FIG. 16 is a flowchart schematically illustrating a method of manufacturing an EUV mask according to an embodiment of the present inventive concept, and FIGS. 17A and 17B are a plan view and a cross-sectional view of an EUV mask corresponding to an operation of forming a reflective multilayer in the method of manufacturing the EUV mask of FIG. 16. FIG. 17B is a cross-sectional view taken along line VI-VI′ of FIG. 17A. The details already described with reference to FIG. 8 or FIG. 13 are briefly described or omitted.

Referring to FIGS. 16, 17A, and 17B, in the method of manufacturing the EUV mask according to an embodiment of the present inventive concept, the reflective multilayer 110d is formed on the substrate 101 (S110b). As shown in FIGS. 17A and 17B, the reflective multilayer 110d may have an area larger than that of the substrate 101. In other words, the reflective multilayer 110d may extend from the top surface of the substrate 101 to cover a portion of the side surface of the substrate 101. For example, the reflective multilayer 110d may cover the entire top surface of the substrate 101, and may cover at least a portion of the side surface of the substrate 101. The side surface of the substrate 101 may correspond to the edge SE of the substrate 101 in plan view. As the reflective multilayer 110d is formed to cover the side surface of the substrate 101, an edge slope area may not be formed in the reflective multilayer 110d on the front surface directly exposed to EUV or directly reflected by EUV. Other details related to the operation S110b of forming the reflective multilayer 110d with reference to FIG. 16 are the same as those related to the operation S110 of forming the reflective multilayer 110 in the method of manufacturing the EUV mask of FIG. 8. In addition, a capping layer may also be changed to correspond to the change in the shape of the reflective multilayer 110d. In other words, the capping layer may cover the top surface of the reflective multilayer 110d on the top surface of the substrate 101 and the reflective multilayer 110d on the side surface of the substrate 101.

Referring to FIG. 16, the operation S120 of forming the absorption layer 130 and the operation S140 of forming the absorption pattern is sequentially performed. By forming the absorption pattern on the absorption layer 130, the EUV mask 100e may be finished. The operation S120 of forming the absorption layer 130 and the operation S140 of forming the absorption pattern with reference to FIG. 16 may be the same as the operation S120 of forming the absorption layer 130 and the operation S140 of forming the absorption pattern of FIG. 8, respectively. Before the operation S120 of forming the absorption layer 130 after the reflective multilayer 110 is formed, the EUV blank mask inspection may be performed. The EUV blank mask inspection may be performed by scanning the reflective multilayer 110d or the capping layer with a laser beam. The EUV blank mask inspection with the laser beam may accurately identify the defect location, and obtain information of defect size and shape for defect mitigation. Since no edge slope area is formed, there is no need to form the defect avoidance pattern. In addition, in the operation S120 of forming the absorption layer 130, an edge trimming process may be performed. Through the edge trimming process, the reflective multilayer 110d, the capping layer, and the absorption layer on the side surface of the substrate 101 may be removed, and a portion of the top surface of the edge of the substrate 101 may be exposed. In other words, the edge trimming process used in the forming of the defect avoidance pattern in the operation S130 of FIG. 8 may be used in the operation S120 of forming the absorption layer 130 of FIG. 16.

According to the method of manufacturing the EUV mask according to an embodiment of the present inventive concept, blister defects occurring in the EUV mask due to the edge slope area may be prevented or avoided by forming the reflective multilayer 110 to cover the side surface of the substrate 101 and removing the edge slope area in the reflective multilayer 110 on the front surface directly exposed to EUV or directly reflected by EUV.

While the present inventive concept has been particularly shown and described with reference to embodiments thereof, it will be understood that various changes in form and details may be made therein without departing from the spirit and scope of the present inventive concept as defined by the appended claims.

1. An extreme ultraviolet (EUV) mask comprising:
a substrate having a rectangular shape;
a reflective multilayer positioned on the substrate and having dozens of alternating layers of two different materials, wherein an edge slope area or a vertical end is formed at an outer edge portion of the reflective multilayer; and
an absorption layer positioned on at least a portion of the reflective multilayer,
wherein the EUV mask has a defect avoidance pattern which opens the edge slope area or the vertical end.

2. The EUV mask of claim 1, wherein the defect avoidance pattern has a rectangular ring shape located at and surrounding along an outer portion of the EUV mask, and
a width of the defect avoidance pattern is greater than a width of the edge slope area in a width direction perpendicular to a longitudinal direction in which the defect avoidance pattern extends.

3. The EUV mask of claim 1, wherein the defect avoidance pattern has a single pattern structure in a rectangular ring shape located at and surrounding along an outer portion of the EUV mask, or
an array pattern structure in which a plurality of fine holes are arranged in a two-dimensional array while having a rectangular ring shape located at and surrounding along the outer portion of the EUV mask.

4. The EUV mask of claim 1, wherein the reflective multilayer includes the edge slope area,
the absorption layer includes a first absorption layer covering a portion of the reflective multilayer and a second absorption layer covering a portion of the substrate outside the reflective multilayer, and
the defect avoidance pattern opens the edge slope area between the first absorption layer and the second absorption layer.

5. The EUV mask of claim 4, wherein the EUV mask further includes a capping layer covering a top surface of the reflective multilayer, an inclined surface of the edge slope area, and a top surface of a portion of the substrate outside the edge slope area toward an edge of the substrate, and
the defect avoidance pattern opens the capping layer corresponding to the edge slope area.

6. The EUV mask of claim 1, wherein the reflective multilayer includes the vertical end,
the absorption layer includes a first absorption layer covering a portion of the reflective multilayer and a second absorption layer covering a portion of the substrate outside the reflective multilayer, and
the defect avoidance pattern is positioned between the first absorption layer and the second absorption layer, and opens a portion of the substrate between the vertical end and the second absorption layer.

7. The EUV mask of claim 6, wherein the EUV mask further comprises a capping layer having a first capping layer covering a top surface of the reflective multilayer and a second capping layer spaced apart from the vertical end and covering a top surface of an outer portion of the substrate, and
the defect avoidance pattern opens a portion of the substrate between the vertical end and the second capping layer.

8. The EUV mask of claim 1, wherein the reflective multilayer includes the edge slope area, and
the defect avoidance pattern opens an entire portion of the substrate outside the edge slope area toward an edge of the substrate.

9. The EUV mask of claim 8, wherein an outermost portion of the edge slope area has a distance of less than about 2 mm from the edge of the substrate.

10. The EUV mask of claim 1, wherein the defect avoidance pattern has a size equal to or greater than a minimum line width on the EUV mask defined by a resolution of an EUV exposure process.

11. An extreme ultraviolet (EUV) mask comprising:
a substrate having a rectangular shape;
a reflective multilayer positioned on the substrate and having dozens of alternating layers of two different materials, wherein an edge slope area or a vertical end is formed at an outer edge portion of the reflective multilayer;
a capping layer having a first capping layer on the reflective multilayer and a second capping layer on the substrate outside the reflective multilayer; and
an absorption layer including a first absorption layer disposed on at least a portion of the first capping layer and a second absorption layer disposed on at least a portion of the second capping layer,
wherein the EUV mask has a defect avoidance pattern which opens a portion of the capping layer covering the edge slope area or a portion of the substrate between the vertical end and the second capping layer.

12. The EUV mask of claim 11, wherein the defect avoidance pattern has a rectangular ring shape located at and surrounding along an outer portion of the EUV mask, and
a width of the defect avoidance pattern is greater than a width of the edge slope area in a width direction perpendicular to a longitudinal direction in which the defect avoidance pattern extends.

13. The EUV mask of claim 11, wherein the defect avoidance pattern has a single pattern structure in a rectangular ring shape located at and surrounding along an outer portion of the EUV mask, or
an array pattern structure in which a plurality of fine holes are arranged in a two-dimensional array while having a rectangular ring shape located at and surrounding along the outer portion of the EUV mask.

14. The EUV mask of claim 11, wherein the reflective multilayer includes the edge slope area,
the first capping layer covers a top surface of the reflective multilayer and an inclined surface of the edge slope area, and the second capping layer extending from the first capping layer covers a portion of the substrate outside the edge slope area toward an edge of the substrate,
the first absorption layer covers a portion of the first capping layer on the top surface of the reflective multilayer, and the second absorption layer is spaced apart from the first capping layer and covers an outer portion of the second capping layer, and
the defect avoidance pattern opens a portion of the capping layer between the first absorption layer and the second absorption layer.

15. The EUV mask of claim 11, wherein the reflective multilayer includes the vertical end;
the first capping layer covers a top surface of the reflective multilayer, and the second capping layer is spaced apart from the first capping layer and covers an outer portion of the substrate;
the first absorption layer covers the first capping layer, and the second absorption layer covers the second capping layer; and
the defect avoidance pattern opens a portion of the substrate between the vertical end and the second capping layer.

16. An extreme ultraviolet (EUV) mask comprising:
a substrate having a rectangular shape;
a reflective multilayer positioned on the substrate and having dozens of alternating layers of two different materials, wherein an edge slope area is formed at an outer edge portion of the reflective multilayer;
a capping layer positioned on the reflective multilayer; and
an absorption layer disposed on at least a portion of the capping layer,
wherein the EUV mask has a defect avoidance pattern which opens the edge slope area or a portion of the capping layer covering the edge slope area.

17. The EUV mask of claim 16, wherein the capping layer includes a first capping layer covering a top surface of the reflective multilayer and an inclined surface of the edge slope area, and a second capping layer extending from the first capping layer and covering a portion of the substrate outside the edge slope area toward an edge of the substrate,
the absorption layer is disposed on a portion of the first capping layer covering the top surface of the reflective multilayer, and
the defect avoidance pattern opens a portion of the first capping layer covering the inclined surface of the edge slope area and an entirety of the second capping layer.

18. The EUV mask of claim 16, wherein the capping layer is disposed on a top surface of the reflective multilayer, and is not disposed on an inclined surface of the edge slope area and a portion of the substrate outside the edge slope area toward an edge of the substrate, and
the defect avoidance pattern opens the inclined surface of the edge slope area and an entire portion of the substrate outside the edge slope area toward the edge of the substrate.

19. The EUV mask of claim 16, wherein an outermost portion of the edge slope area has a distance of less than about 2 mm from an edge of the substrate.

20-29. (canceled)
